(19) United States
(12) Patent Application Publication
(10) Pub. No.: US 2025/0259889 A1
(43) Pub. Date: Aug. 14, 2025

(54) Interconnect Structure of Semiconductor Device

(71) Applicant: Taiwan Semiconductor Manufacturing Co., Ltd., Hsinchu (TW)

(72) Inventors: Yao-Min Liu, Taipei (TW); Chia-Pang Kuo, Taoyuan City (TW); Shu-Cheng Chin, Hsinchu (TW); Chih-Chien Chi, Hsinchu (TW); Cheng-Hui Weng, Hsinchu (TW); Hung-Wen Su, Jhubei City (TW); Ming-Hsing Tsai, Chu-Pei City (TW)

(21) Appl. No.: 19/190,940

(22) Filed: Apr. 28, 2025

Related U.S. Application Data
(63) Continuation of application No. 17/669,665, filed on Feb. 11, 2022, now Pat. No. 12,322,649.
Application No. 17/669,665 is a continuation-in-part of application No. 17/143,496, filed on Jan. 7, 2021, now Pat. No. 11,527,476.
(60) Provisional application No. 63/076,999, filed on Sep. 11, 2020.

(51) Int. Cl. H01L 21/768; H01L 23/522; H01L 23/532

(52) U.S. Cl. CPC H01L 21/76843; H01L 21/76879; H01L 23/5226; H01L 23/53238

(57) ABSTRACT

A method includes forming a first conductive feature in a first dielectric layer. A second dielectric layer is formed over the first conductive feature and the first dielectric layer. An opening is formed in the second dielectric layer. The opening exposes a top surface of the first conductive feature. The top surface of the first conductive feature includes a first metallic material and a second metallic material different from the first metallic material. A native oxide layer is removed from the top surface of the first conductive feature. A surfactant soaking process is performed on the top surface of the first conductive feature. The surfactant soaking process forms a surfactant layer over the top surface of the first conductive feature. A first barrier layer is deposited on a sidewall of the opening. The surfactant layer remains exposed at the end of depositing the first barrier layer.

### PRIORITY CLAIM AND CROSS-REFERENCE

This application is a continuation of U.S. patent application Ser. No. 17/669,665, filed on Feb. 11, 2022, which is a continuation-in-part of U.S. patent application Ser. No. 17/143,496, filed on Jan. 7, 2021, now U.S. Pat. No. 11,527,476, issued Dec. 13, 2022, which claims the benefit of U.S. Provisional Application No. 63/076,999, filed on Sep. 11, 2020, each application is hereby incorporated herein by reference.

### BACKGROUND

Generally, active devices and passive devices are formed on and in a semiconductor substrate. Once formed, these active devices and passive devices may be connected to each other and to external devices using a series of conductive and insulating layers. These layers may help to interconnect the various active devices and passive devices as well as provide an electrical connection to external devices through, for example, a contact pad.

To form these interconnections within these layers, a series of photolithographic, etching, deposition, and planarization techniques may be employed. However, the use of such techniques has become more complicated as the size of active and passive devices have been reduced, causing a reduction in the size of the interconnects to be desired as well. As such, improvements in the formation and structure of the interconnects is desired in order to make the overall devices smaller, cheaper, and more efficient with fewer defects or problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 5, 6, 8-10, 11A, 11B, 12A, 12B, and 13-28 illustrate cross-sectional views of various intermediate stages of fabrication of a semiconductor device in accordance with some embodiments.

FIG. 3A is a flow diagram illustrating a method of forming a barrier layer in accordance with some embodiments.

FIG. 3B is a flow diagram illustrating a surfactant soaking process in accordance with some embodiments.

FIG. 3C is a flow diagram illustrating a surfactant soaking process in accordance with some embodiments.

FIG. 4 illustrates a schematic view of an apparatus for forming a barrier layer in accordance with some embodiments.

FIGS. 7A-7C illustrate various surfactant molecules in accordance with some embodiments.

FIG. 29 illustrates concentration profiles of various elements within conductive features in accordance with some embodiments.

FIGS. 30-34 illustrate cross-sectional views of a semiconductor device in accordance with some embodiments.

FIGS. 35-37 illustrate cross-sectional views of a semiconductor device in accordance with some embodiments.

FIGS. 38-40 illustrate cross-sectional views of a semiconductor device in accordance with some embodiments.

FIGS. 41-49 illustrate cross-sectional views of various intermediate stages of fabrication of a semiconductor device in accordance with some embodiments.

FIGS. 50-52 illustrate cross-sectional views of a semiconductor device in accordance with some embodiments.

FIG. 53 illustrates a cross-sectional view of a semiconductor device in accordance with some embodiments.

FIG. 54 illustrates a cross-sectional view of a semiconductor device in accordance with some embodiments.

FIG. 55 illustrates a cross-sectional view of a semiconductor device in accordance with some embodiments.

FIG. 56 illustrates a cross-sectional view of a semiconductor device in accordance with some embodiments.

FIG. 57 is a flow diagram illustrating a method of forming an interconnect structure in accordance with some embodiments.

FIG. 58 is a flow diagram illustrating a surface modification process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to a specific context, namely, an interconnect structure of a semiconductor device and a method of forming the same. Some embodiments allow for altering a deposition rate of a barrier layer on a surface of a first conductive feature that is exposed by an opening in an overlying dielectric layer, such that the deposition rate on the bottom of the opening (i.e., on the exposed surface of the first conductive feature) is reduced or suppressed, and such that the barrier layer is selectively deposited on sidewalls of the opening and not on the bottom of the opening. In some embodiments, the deposition rate of the barrier layer on the bottom of the opening may be reduced or suppressed by performing a surface modification process on the exposed surface of the first conductive feature. In some embodiments, the surface modification process includes performing an oxide reduction process on the exposed surface of the conductive feature followed by performing a surfactant soaking process on the exposed surface of the conductive feature. Various embodiments discussed herein allow for reducing an amount of the barrier layer within the opening and reducing a contact resistance between the first conductive feature and a second conductive feature formed in the opening.

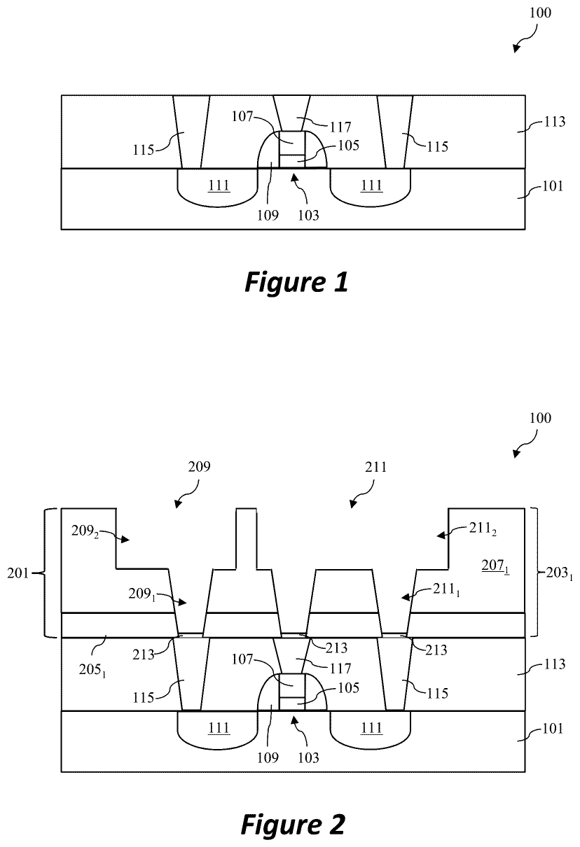

FIGS. 1, 2, 5, 6, 8-10, 11A, 11B, 12A, 12B, and 13-28 illustrate cross-sectional views of various intermediate stages of fabrication of a semiconductor device 100 in accordance with some embodiments. Referring to FIG. 1, the process for forming the semiconductor device 100 comprises providing a substrate 101. The substrate 101 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 101 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more active and/or passive devices 103 (illustrated in FIG. 1 as a single transistor) are formed on the substrate 101. The one or more active and/or passive devices 103 may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also used as appropriate for a given application.

In some embodiments, the transistor 103 includes a gate stack comprising a gate dielectric 105 and a gate electrode 107, spacers 109 on opposite sidewalls of the gate stack, and source/drain regions 111 adjacent to the respective spacers 109. For simplicity, components that are commonly formed in integrated circuits, such as gate silicides, source/drain silicides, contact etch stop layers, and the like, are not illustrated. In some embodiments, the transistor 103 may be formed using any acceptable methods. In some embodiments, the transistor 103 may be a planar MOSFET, a FinFET, or the like.

In some embodiments, one or more interlayer dielectric (ILD) layers 113 are formed over the substrate and the one or more active and/or passive devices 103. In some embodiments, the one or more ILD layers 113 may comprise, for example, phosphosilicate glass (PSG), borophosphosilicate glass (BPSG), fluorosilicate glass (FSG), SiOxCy, Spin-On-Glass, Spin-On-Polymers, silicon carbon material, compounds thereof, composites thereof, combinations thereof, or the like, and may be formed by any suitable method, such as spin-on coating, chemical vapor deposition (CVD), plasma-enhanced CVD (PECVD), atomic layer deposition (ALD), a combination thereof, or the like.

In some embodiments, source/drain contact plugs 115 and a gate contact plug 117 are formed in the one or more ILD layers 113. The source/drain contact plugs 115 provide electrical contacts to the source/drain regions 111. The gate contact plug 117 provides electrical contact to the gate electrode 107. In some embodiments, the steps for forming the contact plugs 115 and 117 include forming openings in the one or more ILD layers 113, depositing one or more barrier/adhesion layers (not explicitly shown) in the openings, depositing seed layers (not explicitly shown) over the one or more barrier/adhesion layers, and filling the openings with a conductive material (not explicitly shown). A chemical mechanical polishing (CMP) is then performed to remove excess materials of the one or more barrier/adhesion layers, the seed layers, and the conductive material overfilling the openings. In some embodiments, topmost surfaces of the contact plugs 115 and 117 are substantially coplanar or level with a topmost surface of the one or more ILD layers 113 within process variations of the CMP process.

In some embodiments, the one or more barrier/adhesion layers may comprise titanium, titanium nitride, tantalum, tantalum nitride, a combination thereof, a multilayer thereof, or the like, and may be formed using physical vapor deposition (PVD), CVD, ALD, a combination thereof, or the like. The one or more barrier/adhesion layers protect the one or more ILD layers 113 from diffusion and metallic poisoning. The seed layers may comprise copper, titanium, nickel, gold, manganese, a combination thereof, a multilayer thereof, or the like, and may be formed by ALD, CVD, PVD, sputtering, a combination thereof, or the like. The conductive material may comprise copper, aluminum, tungsten, cobalt, ruthenium, molybdenum, combinations thereof, alloys thereof, multilayers thereof, or the like, and may be formed using, for example, plating, or other suitable methods.

FIGS. 2, 5, 6, 8-10, 11A, 11B, 12A, 12B, and 13-28 illustrate cross-sectional views of various intermediate stages of fabrication of an interconnect structure 201 over the structure of FIG. 1 in accordance with some embodiments. Referring to FIG. 2, in some embodiments, the steps for forming the interconnect structure 201 starts with forming a metallization layer 203₁ over the one or more ILD layers 113 and the contact plugs 115 and 117. In some embodiments, the formation of the metallization layer 203₁ starts with forming an etch stop layer (ESL) 205₁ over the one or more ILD layers 113 and the contact plugs 115 and 117, and forming an inter-metal dielectric (IMD) layer 207₁ over the ESL 205₁.

In some embodiments, a material for the ESL 205₁ is chosen such that an etch rate of the ESL 205₁ is less than an etch rate of the IMD layer 207₁. In some embodiments, the ESL 205₁ may comprise one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, CVD, PECVD, ALD, a combination thereof, or the like. In some embodiments, the IMD layer 207₁ may be formed using similar materials and methods as the one or more ILD layers 113 described above with reference to FIG. 1, and the description is not repeated herein. In some embodiments, the one or more ILD layers 113 and the IMD layer 207₁ may comprise a same material. In other embodiments, the one or more ILD layers 113 and the IMD layer 207₁ may comprise different materials.

Referring further to FIG. 2, the IMD layer 207₁ and the ESL 205₁ are patterned to form openings 209 and 211 in the IMD layer 207₁ and the ESL 205₁. In some embodiments, the opening 209 exposes a top surface of the source/drain contact plug 115, and the opening 211 exposes a top surface of the source/drain contact plug 115 and a top surface of the gate contact plug 117. The opening 209 comprises a lower portion 209₁, which may be also referred to as a via opening 209₁, and an upper portion 2092, which may be also referred to as a line opening 2092. The opening 211 comprises lower portions 211₁, which may be also referred to as via openings 211₁, and an upper portion 2112, which may be also referred to as a line opening 2112. In some embodiments, the openings 209 and 211 may be formed by a “via first” process. In such embodiments, the via openings of the openings 209 and 211 are formed before the line openings of the openings 209 and 211. In other embodiments, the openings 209 and 211 may be formed by a “trench first” process. In such embodiments, the via openings of the openings 209 and 211 are formed after the line openings of the openings 209 and 211. In some embodiments, the openings 209 and 211 may be formed using suitable photolithography and etching processes. The etching processes may include one or more dry etching processes. The etching processes may be anisotropic.

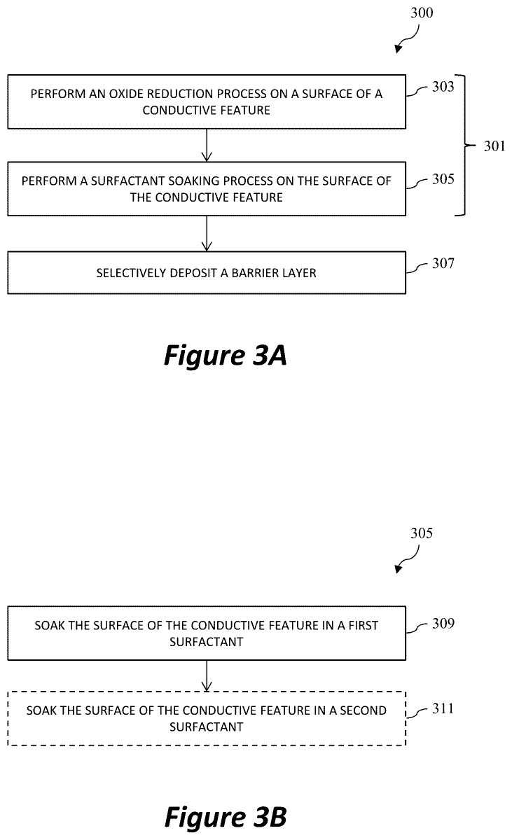

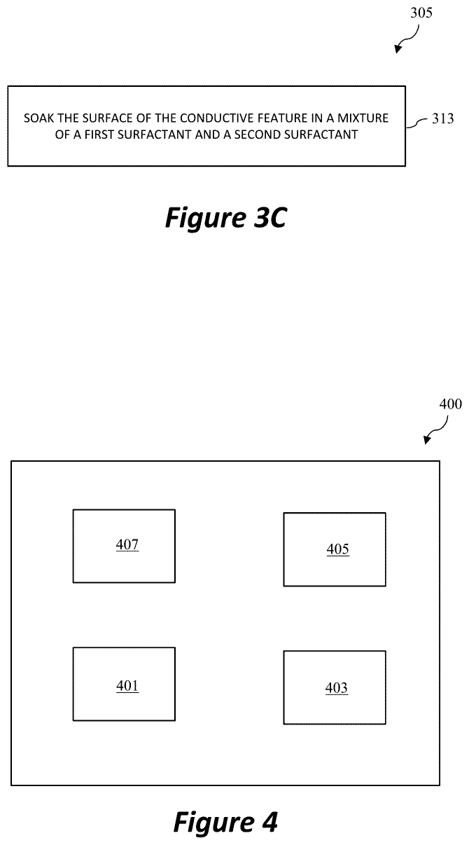

In some embodiments, after forming the openings 209 and 211, the resulting structure is transferred to an apparatus 400 (see Figure) for forming a barrier layer as described below with reference to FIGS. 3A-3C, 4-6, 7A-7C, 8-10, 11A, 11B, 12A, 12B, and 13-15. In some embodiment, the transferring process may break the vacuum and oxide layers 213 may be formed on the exposed surfaces of the contact plugs 115 and 117. The oxide layers 213 are native oxide layers. In some embodiments when the contact plugs 115 and 117 comprise a metallic material, the oxide layers 213 comprise an oxide of the metallic material.

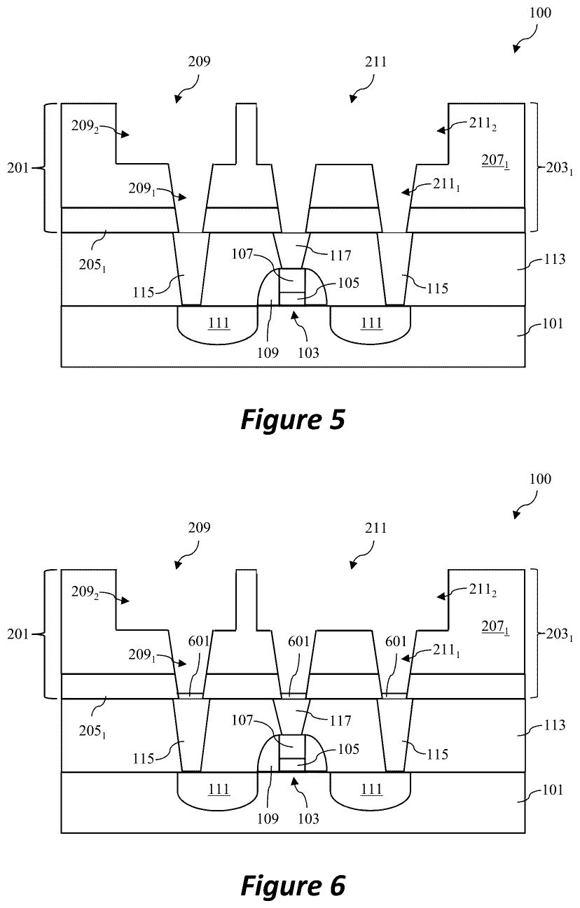

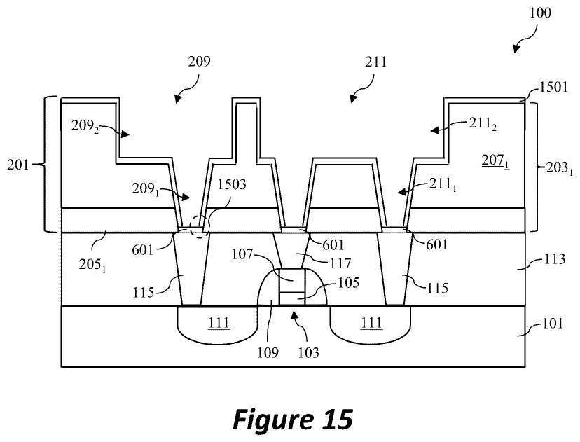

FIG. 3A is a flow diagram illustrating a method 300 of forming a barrier layer 1501 (see FIG. 15) in the openings 209 and 211 (see FIG. 2) in accordance with some embodiments. FIGS. 3B and 3C are flow diagrams illustrating a surfactant soaking process 305 performed in the method 300 in accordance with some embodiments. FIG. 4 illustrates a schematic view of an apparatus 400 for forming the barrier layer 1501 in accordance with some embodiments. FIGS. 5, 6, 7A-7C, 8-10, 11A, 11B, 12A, 12B, and 13-15 illustrate cross-sectional views of various intermediate stages of fabrication of the barrier layer 1501 in the openings 209 and 211 in accordance with the method 300.

Referring to FIGS. 3A, 4, and 5, the method 300 starts with step 301 when a surface modification process is performed on the exposed on the exposed surfaces of contact plugs 115 and 117. In some embodiments, step 301 comprises steps 303 and 305. In step 303, an oxide reduction process is performed on the oxide layers 213 (see FIG. 2) to remove oxygen from the oxide layers 213. In some embodiments when the oxide layers 213 comprise an oxide of a metallic material, the oxide reduction process removes oxygen from the oxide of the metallic material and leaves the metallic material behind. In some embodiments, the oxide reduction process comprises performing a plasma process on the oxide layers 213.

In some embodiments, the plasma process is performed by a plasma module 401 of the apparatus 400. In such embodiments, the structure of FIG. 2 is loaded into the plasma module 401 for performing the plasma process. The plasma module may be a remote plasma module or a direct plasma module. In some embodiments, the plasma process uses a plasma generated from a gas comprising H₂, Ar, a combination thereof, or the like.

In some embodiments when the oxide layers 213 comprise copper oxide, cobalt oxide, or ruthenium oxide, the plasma process may comprise an H₂ plasma process. In some embodiments, the H₂ plasma process is a remote plasma process with a positive ion filter, and may be performed at a temperature between about 300° C. and 350° C., and at a pressure between about 0.2 Torr to 3 Torr. In some embodiments, in addition to removing oxygen from the oxide layers 213, the H₂ plasma process may also remove etch byproducts formed on sidewalls and bottoms of the openings 209 and 211 during the etching process for forming the openings 209 and 211 (see FIG. 2).

In some embodiments wherein the oxide layers 213 (see FIG. 2) comprise tungsten oxide, the H₂ plasma process may not be efficient for removing oxygen from the tungsten oxide without causing carbon depletion of a low-k material of the IMD layer 207₁. In such embodiments, the plasma process comprises an Ar plasma process followed by the H₂ plasma process. In some embodiments, the Ar plasma process is a direct plasma process, and may be performed at a temperature between about 300° C. and 350° C., and at a pressure between about 2 mTorr to 30 mTorr.

Referring to FIGS. 3A-3C, 4, and 6, in step 305, a surfactant soaking process is performed on the structure of FIG. 5. The surfactant soaking process alters exposed top surfaces of conductive features (such as, for example, the contact plugs 115 and 117). In some embodiments, the surfactant soaking process may be performed by soaking modules 403 and 405 of the apparatus 400. In some embodiments, the surfactant soaking process comprises steps 309 and 311 (see FIG. 3B). In step 309, the structure of FIG. 5 is soaked in a gas of first surfactant molecules. In step 311, the structure of FIG. 5 is soaked in a gas of second surfactant molecules different from the first surfactant molecules. In some embodiments, step 311 may be omitted.

In some embodiments when step 311 is omitted, the step 309 is performed by the soaking module 403 and the soaking module 405 is not used. In such embodiments, in step 309, the structure of FIG. 5 is transferred from the plasma module 401 into the soaking module 403 and the gas of the first surfactant molecules is flown into a chamber of the soaking module 403. As described below in greater detail, such embodiments may be used when the top surfaces of conductive features (such as, for example, the contact plugs 115 and 117) comprises a single metallic material, or when the top surfaces of the conductive features (such as, for example, the contact plugs 115 and 117) comprise two or more metallic materials.

In some embodiments when both step 309 and 311 are performed, both step 309 and 311 are performed by the soaking module 403 and the soaking module 405 is not used. In such embodiments, in step 309, the structure of FIG. 5 is transferred from the plasma module 401 into the soaking module 403 and the gas of the first surfactant molecules is flown into the chamber of the soaking module 403. After completing step 309, in step 911, the gas of the second surfactant molecules is flown in the chamber of the soaking module 403. As described below in greater detail, such embodiments may be used when the top surfaces of the conductive features (such as, for example, the contact plugs 115 and 117) comprise two or more metallic materials.

In some embodiments when both step 309 and 311 are performed, step 309 is performed by the soaking module 403 and step 311 is performed by the soaking module 405. In such embodiments, in step 309, the structure of FIG. 5 is transferred from the plasma module 401 into the soaking module 403 and the gas of the first surfactant molecules is flown into the chamber of the soaking module 403. After completing step 309, in step 911, the structure of FIG. 5 is transferred from the soaking module 403 into the soaking module 405 and the gas of the second surfactant molecules is flown into a chamber of the soaking module 405. As described below in greater detail, such embodiments may be used when the top surfaces of the conductive features (such as, for example, the contact plugs 115 and 117) comprise two or more metallic materials.

In some embodiments, the surfactant soaking process comprises step 313 (see FIG. 3C). In step 313, the structure of FIG. 5 is soaked in a gas comprising a mixture of first surfactant molecules and second surfactant molecules different from the first surfactant molecules. In some embodiments, step 313 is performed by the soaking module 403 and the soaking module 405 is not used. In such embodiments, in step 313, the structure of FIG. 5 is transferred from the plasma module 401 into the soaking module 403 and the gas comprising the mixture of the first surfactant molecules and the second surfactant molecules is flown into the chamber of the soaking module 403. As described below in greater detail, such embodiments may be used when the top surfaces of the conductive features (such as, for example, the contact plugs 115 and 117) comprise two or more metallic materials.

In some embodiments, the surfactant soaking process is performed for a soaking process time between about 20 sec to about 300 sec. In some embodiments, the surfactant soaking process forms surfactant layers 601 on the exposed top surfaces of the contact plugs 115 and 117. In some embodiments, the surfactant layers 601 are not formed on surfaces of the IMD layer 207₁ exposed by the openings 209 and 211. In some embodiments, the surfactant layers 601 may comprises one or more layers of the surfactant molecules. Each of the surfactant layers 601 may be a monolayer. In some embodiments, the surfaces of the IMD layer 207₁ exposed by the openings 209 and 211 may be free from surfactant molecules. As described below in greater detail, the surfactant layers 601 prevent the barrier layer from forming over top surface of the conductive features (such as, for example, the contact plugs 115 and 117).

In some embodiments, the surfactant molecules comprise functional groups (also referred to as head groups) that bind to metal atoms of the conductive features (such as, for example, the contact plugs 115 and 117). The surfactant molecules may be unsaturated hydrocarbon molecules (such as alkene molecules, alkyne molecules, aromatic compounds, or the like) that comprise unsaturated carbon functional groups, molecules (such as alkylamine molecules, monoamine molecules, diamine molecules, triamine molecules, tetraamine molecules, or the like) that comprise nitrogen-based functional groups such as amine functional groups, molecules (such as aminoalkyne molecules, or the like) that comprise more than one functional group, or the like. In some embodiments when the surfactant molecules are molecules that comprise more than one functional group, each surfactant molecule may comprise an unsaturated carbon functional group, a nitrogen-based functional group (such as amine functional group), a combination thereof, or any functional group that binds to metal atoms. In some embodiments when the surfactant molecules are aminoalkyne molecules, each surfactant molecule comprises an unsaturated carbon functional group and a nitrogen-based functional group (such as amine functional group). The alkene molecules have a chemical formula CₙH₂ₙ₊₁CH═CHCₘH₂ₘ₊₁, with n and m being in a range from 0 to 10, and with n and m being equal or different from one another. The alkyne molecules have a chemical formula CₙH₂ₙ₊₁C≡CCₘH₂ₘ₊₁, with n and m being in a range from 0 to 10, and with n and m being equal or different from one another. The alkylamine molecules have a chemical formula CₙH₂ₙ₊₁NH₂, with n being in a range from 1 to 10, a chemical formula (CₙH₂ₙ₊₁)(CₘH₂ₘ₊₁)NC₂H₄N(CⱼH₂ⱼ₊₁)(CₖH₂ₖ₊₁), with n, m, j and k being in a range from 0 to 10, a chemical formula (CₙH₂ₙ₊₁)(CₘH₂ₘ₊₁)NC₂H₄N(C₁H₂ₗ₊₁) C₂H₄N(CⱼH₂ⱼ₊₁)(CₖH₂ₖ₊₁), with n, m, j, k and l being in a range from 0 to 10, or a chemical formula N(C₂H₄N)₃(CₙH₂ₙ₊₁)(CₘH₂ₘ₊₁) (CⱼH₂ⱼ₊₁)(CₖH₂ₖ₊₁)(CᵢH₂ᵢ₊₁)(CₕH₂ₕ₊₁), with n, m, j, k, i and h being in a range from 0 to 10.

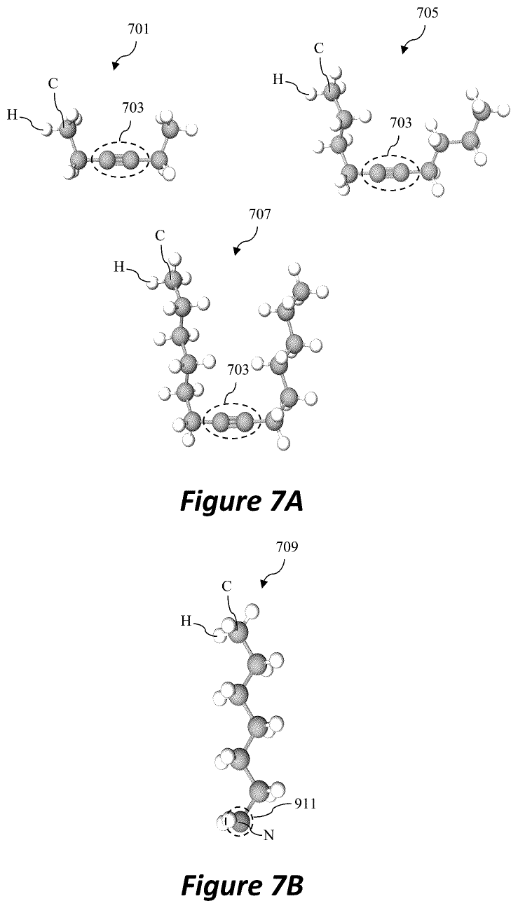

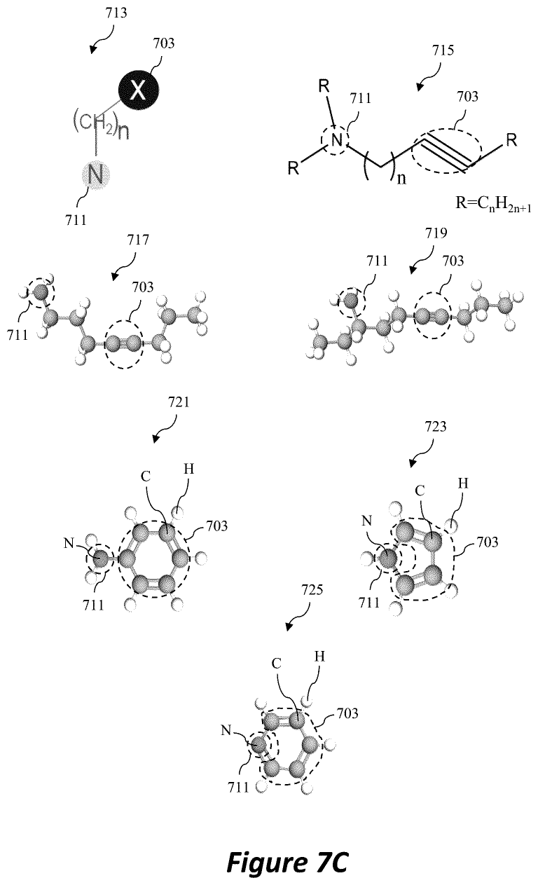

FIG. 7A illustrate various surfactant molecules in accordance with some embodiments. The surfactant molecules 701, 705 and 707 are alkyne molecules that comprise unsaturated carbon functional groups 703 such as alkyne moieties. The surfactant molecule 701 has a chemical formula C₂H₅C≡CC₂H₅. The surfactant molecule 705 has a chemical formula C₄H₉C≡CC₄H₉. The surfactant molecule 707 has a chemical formula C₆H₁₃C≡CC₆H₁₃. A length of the surfactant molecule 705 is greater than a length of the surfactant molecule 701. A length of the surfactant molecule 707 is greater than lengths of the surfactant molecules 701 and 705. The surfactant molecules 701, 705 and 707 bond to a metallic material through the unsaturated carbon functional groups 703. Longer surfactant molecules provide enhanced electron density of C≡C bonds and enhanced coverage of the surface of the metallic material per adsorbed surfactant molecule.

FIG. 7B illustrates a surfactant molecule in accordance with some embodiments. The surfactant molecule 709 is an alkylamine molecule having a nitrogen-based functional group 711 at one end of the molecule. The surfactant molecule 709 has a chemical formula C₆H₁₃NH₂. The surfactant molecule 709 bonds to a metallic material through the nitrogen-based functional group 711.

FIG. 7C illustrate various surfactant molecules in accordance with some embodiments. The surfactant molecules 713, 715, 717, 719, 721, 723, and 725 are molecules that comprise both unsaturated carbon functional groups 703 and nitrogen-based functional groups 711. The surfactant molecule 713 is a linear molecule comprising an unsaturated carbon functional group 703 at one end of the molecule and a nitrogen-based functional group 711 at opposite end of the molecule. The surfactant molecule 715 is a linear molecule comprising an unsaturated carbon functional group 703 at an interior of the molecule and a nitrogen-based functional group 711 at one end of the molecule, with R being a hydrocarbon such as, for example, CₙH₂ₙ₊₁. The surfactant molecule 717 is a linear molecule comprising an unsaturated carbon functional group 703 at an interior of the molecule and a nitrogen-based functional group 711 at one end of the molecule. The surfactant molecule 719 is a linear molecule comprising an unsaturated carbon functional group 703 and a nitrogen-based functional group 711 at an interior of the molecule. The surfactant molecule 721 is a cyclic molecule comprising a ring of carbon atoms, the ring comprising unsaturated carbon functional groups 703, and a nitrogen-based functional group 711 being bonded to the ring. The surfactant molecule 723 is a heterocyclic molecule comprising a ring made of carbon and nitrogen atoms, the ring comprising unsaturated carbon functional groups 703 and a nitrogen-based functional group 711. The surfactant molecule 725 is a heterocyclic molecule comprising a ring made of carbon and nitrogen atoms, the ring comprising unsaturated carbon functional groups 703 and a nitrogen-based functional group 711. As described below in greater detail, the surfactant molecules 713, 715, 717, 719, 721, 723, and 725 bond to a metallic material through unsaturated carbon functional groups 703 or nitrogen-based functional groups 711 depending on the electropositivity of the metallic material.

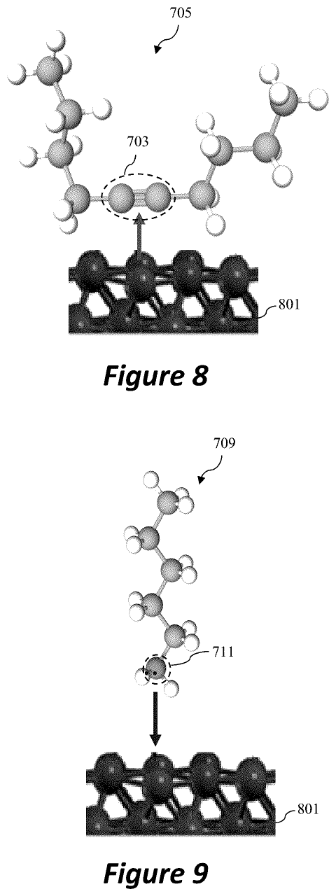

FIG. 8 illustrates a cross-sectional view of a surfactant soaking process performed on a surface of a metallic layer 801 in accordance with some embodiments. The metallic layer 801 may be a top portion of a conductive feature (such as, for example, the contact plug 115 or 117 illustrated in FIG. 5). The metallic layer 801 may comprise tungsten, molybdenum, cobalt, ruthenium, or copper, which have been ordered according to decreasing electropositivity. In some embodiments when surfactant molecules comprise molecules having the unsaturated carbon functional groups 703 such as, for example, the surfactant molecule 705, the surfactant molecules are bonded to atoms of the metallic layer 801 through the unsaturated carbon functional groups 703. Bond strength between the unsaturated carbon functional group 703 and an atom of the metallic layer 801 is greater for the metallic layer 801 having a lesser electropositivity. Bond strength between the unsaturated carbon functional group 703 and a copper atom is greater than bond strength between the unsaturated carbon functional group 703 and a ruthenium atom. Bond strength between the unsaturated carbon functional group 703 and a ruthenium atom is greater than bond strength between the unsaturated carbon functional group 703 and a cobalt atom. Bond strength between the unsaturated carbon functional group 703 and a cobalt atom is greater than bond strength between the unsaturated carbon functional group 703 and a molybdenum atom. Bond strength between the unsaturated carbon functional group 703 and a molybdenum atom is greater than bond strength between the unsaturated carbon functional group 703 and a tungsten atom. Accordingly, due to the strong bonding, the surfactant molecules having unsaturated carbon functional groups 703 sufficiently cover the metallic layer 801 made of copper. Furthermore, due to the weak bonding, the surfactant molecules having unsaturated carbon functional groups 703 may partially cover or do not cover the metallic layer 801 made of tungsten, molybdenum, cobalt, or ruthenium. In some embodiments when the metallic layer 801 is made of tungsten, molybdenum, cobalt, or ruthenium, the surfactant molecules having unsaturated carbon functional groups 703 may not be used while performing the surfactant soaking process.

FIG. 9 illustrates a cross-sectional view of a surfactant soaking process performed on the surface of the metallic layer 801 in accordance with some embodiments. In some embodiments when surfactant molecules comprise molecules having the nitrogen-based functional groups 711 such as, for example, the surfactant molecule 709, the surfactant molecules are bonded to atoms of the metallic layer 801 through the nitrogen-based functional groups 711. Bond strength between the nitrogen-based functional groups 711 and an atom of the metallic layer 801 is greater for metallic layer 801 having a greater electropositivity. Bond strength between the nitrogen-based functional groups 711 and a tungsten atom is greater than bond strength between the nitrogen-based functional groups 711 and a molybdenum atom. Bond strength between the nitrogen-based functional groups 711 and a molybdenum atom is greater than bond strength between the nitrogen-based functional groups 711 and a cobalt atom. Bond strength between the nitrogen-based functional groups 711 and a cobalt atom is greater than bond strength between the nitrogen-based functional groups 711 and a ruthenium atom. Bond strength between the nitrogen-based functional groups 711 and a ruthenium atom is greater than bond strength between the nitrogen-based functional groups 711 and a copper atom. Accordingly, due to the strong bonding, the surfactant molecules having nitrogen-based functional groups 711 sufficiently cover the metallic layer 801 made of tungsten, molybdenum, cobalt, or ruthenium. Furthermore, due to the weak bonding, the surfactant molecules having nitrogen-based functional groups 711 partially cover or do not cover the metallic layer 801 made of copper. In some embodiments when the metallic layer 801 is made of copper, the surfactant molecules having nitrogen-based functional groups 711 may not be used while performing the surfactant soaking process.

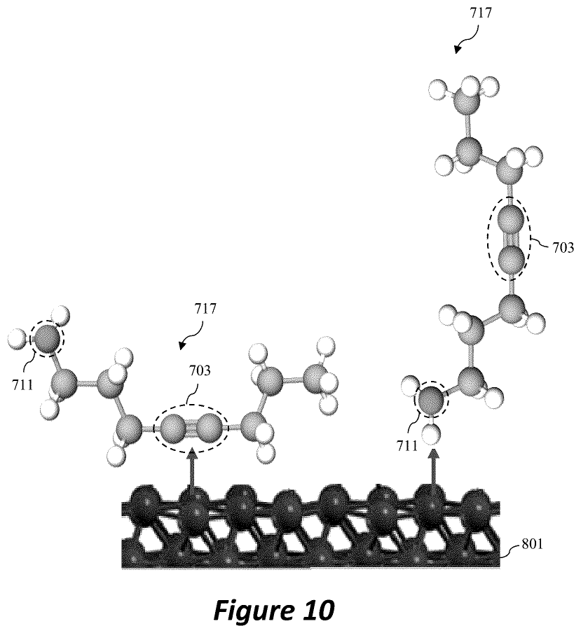

FIG. 10 illustrates a cross-sectional view of a surfactant soaking process performed on a surface of a metallic layer 801 in accordance with some embodiments. In some embodiments when surfactant molecules comprise molecules having both unsaturated carbon functional groups 703 and the nitrogen-based functional groups 711 such as, for example, the surfactant molecules 717, the surfactant molecules are bonded to atoms of the metallic layer 801 through the unsaturated carbon functional groups 703 or the nitrogen-based functional groups 711. In some embodiments when the metallic layer 801 is made of copper, surfactant molecules are bonded to atoms of the metallic layer 801 through the unsaturated carbon functional groups 703. In some embodiments when the metallic layer 801 is made of tungsten, molybdenum, cobalt, or ruthenium, surfactant molecules are bonded to atoms of the metallic layer 801 through the nitrogen-based functional groups 711.

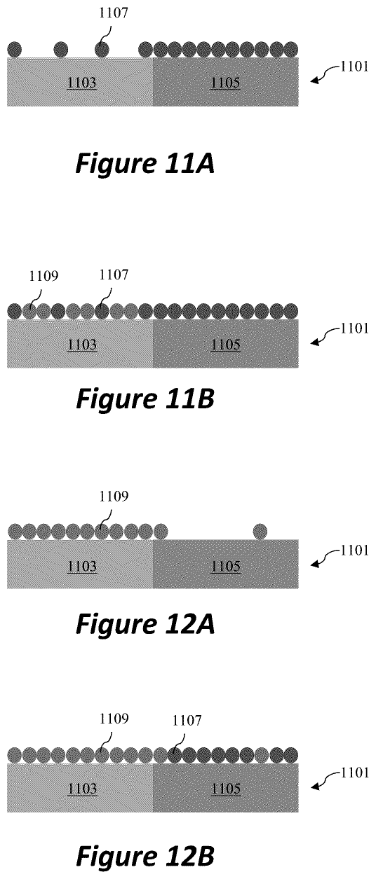

FIGS. 11A and 11B illustrate cross-sectional views of a surfactant soaking process performed on a surface of a metallic layer 1101 in accordance with some embodiments. The metallic layer 1101 may comprise a first metallic material 1103 and a second metallic material 1105 different from the first metallic material 1103. The first metallic material 1103 may be more electropositive than the second metallic material 1105. The first metallic material 1103 may be made of tungsten, molybdenum, cobalt, ruthenium, or a combination thereof. The second metallic material 1105 may be made of copper. In some embodiments, the surfactant soaking process may be performed according to the method 305 (see FIG. 3B).

Referring to FIG. 11A, the surface of the metallic layer 1101 is soaked in a gas of surfactant molecules 1107. The surfactant molecules 1107 may be molecules having only unsaturated carbon functional groups. The surfactant molecules 1107 are adsorbed on the surface of the metallic layer 1101, such that the surfactant molecules 1107 partially cover a surface of the first metallic material 1103 and fully cover a surface of the second metallic material 1105 due to the difference in electropositivity. The surfactant molecules 1107 are adsorbed on the surface of the metallic layer 1101 through unsaturated carbon functional groups (such as, for example, unsaturated carbon functional groups 703 illustrated in FIG. 7A).

Referring to FIG. 11B, the surface of the metallic layer 1101 is soaked in a gas of surfactant molecules 1109. The surfactant molecules 1109 may be molecules having only nitrogen-based functional groups. The surfactant molecules 1109 are adsorbed on the surface of the metallic layer 1101 such that the surfactant molecules 1109 fully cover the uncovered portions of the surface of the first metallic material 1103. The surfactant molecules 1109 are adsorbed on the surface of the metallic layer 1101 through nitrogen-based functional groups (such as, for example, nitrogen-based functional groups 711 illustrated in FIG. 7B). In some embodiments, the adsorbed surfactant molecules 1107 and 1109 form a surfactant layer on the surface of the metallic layer 1101.

In some embodiments, the surfactant soaking process described above with reference to FIGS. 11A and 11B is performed using a single soaking module (such as, for example, the soaking module 403 or 405 of the apparatus 400 illustrated in FIG. 4). In other embodiments, the process steps described above with reference to FIG. 11A is performed using a first soaking module (such as, for example, the soaking module 403 of the apparatus 400 illustrated in FIG. 4) and the process steps described above with reference to FIG. 11B is performed using a second soaking module (such as, for example, the soaking module 405 of the apparatus 400 illustrated in FIG. 4).

FIGS. 12A and 12B illustrate cross-sectional views of a surfactant soaking process performed on the surface of the metallic layer 1101 in accordance with some embodiments. In some embodiments, the surfactant soaking process may be performed according to the method 305 (see FIG. 3B). Referring to FIG. 12A, the surface of the metallic layer 1101 is soaked in a gas of surfactant molecules 1109. The surfactant molecules 1109 may be molecules having only nitrogen-based functional groups. The surfactant molecules 1109 are adsorbed on the surface of the metallic layer 1101, such that surfactant molecules 1109 fully cover the surface of the first metallic material 1103 and partially cover the surface of the second metallic material 1105 due to the difference in electropositivity. The surfactant molecules 1109 are adsorbed on the surface of the metallic layer 1101 through nitrogen-based functional groups (such as, for example, nitrogen-based functional groups 711 illustrated in FIG. 7B).

Referring to FIG. 12B, the surface of the metallic layer 1101 is soaked in a gas of surfactant molecules 1107. The surfactant molecules 1107 may be molecules having only unsaturated carbon functional groups. The surfactant molecules 1107 are adsorbed on the surface of the metallic layer 1101, such that surfactant molecules 1107 fully cover the uncovered portions of the surface of the second metallic material 1105. The surfactant molecules 1107 are adsorbed on the surface of the metallic layer 1101 through unsaturated carbon functional groups (such as, for example, unsaturated carbon functional groups 703 illustrated in FIG. 7A). In some embodiments, the adsorbed surfactant molecules 1107 and 1109 form a surfactant layer on the surface of the metallic layer 1101.

In some embodiments when the first metallic material 1103 is made of cobalt, by soaking the metallic layer 1101 first in the surfactant molecules 1109 and subsequently in the surfactant molecules 1107, carbide formation due to bonding of cobalt and unsaturated hydrocarbons is reduced or avoided.

In some embodiments, the surfactant soaking process described above with reference to FIGS. 12A and 12B is performed using a single soaking module (such as, for example, the soaking module 403 or 405 of the apparatus 400 illustrated in FIG. 4). In other embodiments, the process steps described above with reference to FIG. 21A is performed using a first soaking module (such as, for example, the soaking module 403 of the apparatus 400 illustrated in FIG. 4) and the process steps described above with reference to FIG. 12B is performed using a second soaking module (such as, for example, the soaking module 405 of the apparatus 400 illustrated in FIG. 4).

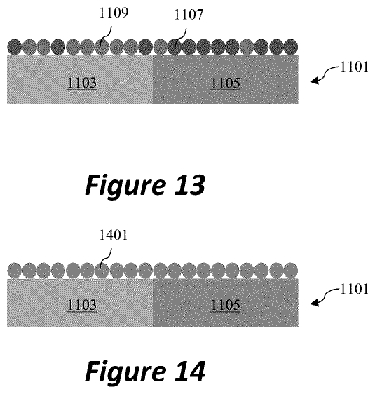

FIG. 13 illustrates a cross-sectional view of a surfactant soaking process performed on the surface of the metallic layer 1101 in accordance with some embodiments. In some embodiments, the surfactant soaking process may be performed according to the method 305 (see FIG. 3C). In some embodiments, the surface of the metallic layer 1101 is soaked in a gas comprising a mixture of surfactant molecules 1107 and 1109. The surfactant molecules 1107 and 1109 are adsorbed to the surface of the metallic layer 1101, such that the surface of the first metallic material 1103 is predominantly covered by the surfactant molecules 1109 and portions of the surface of the first metallic material 1103 not covered by the surfactant molecules 1109 are covered by the surfactant molecules 1107 due to the difference in electropositivity. Furthermore, the surface of the second metallic material 1105 is predominantly covered by the surfactant molecules 1107 and portions of the surface of the second metallic material 1105 not covered by the surfactant molecules 1107 are covered by the surfactant molecules 1109 due to the difference in electropositivity. The surfactant molecules 1107 are adsorbed on the surface of the metallic layer 1101 through unsaturated carbon functional groups (such as, for example, unsaturated carbon functional groups 703 illustrated in FIG. 7A). The surfactant molecules 1109 are adsorbed on the surface of the metallic layer 1101 through nitrogen-based functional groups (such as, for example, nitrogen-based functional groups 711 illustrated in FIG. 7B). The adsorbed surfactant molecules 1107 and 109 form a surfactant layer on the surface of the metallic layer 1101. In some embodiments, the surfactant soaking process described above with reference to FIG. 13 is performed using a single soaking module (such as, for example, the soaking module 403 or 405 of the apparatus 400 illustrated in FIG. 4).

FIG. 14 illustrates a cross-sectional view of a surfactant soaking process performed on the surface of the metallic layer 1101 in accordance with some embodiments. In some embodies, the surfactant soaking process may be performed according to step 309 of the method 305 (see FIG. 3B). In some embodiments, the surface of the metallic layer 1101 is soaked in a gas of surfactant molecules 1401. The surfactant molecules 1401 may be molecules having both unsaturated carbon functional groups and nitrogen-based functional groups. The surfactant molecules 1401 are adsorbed on the surface of the metallic layer 1101, such that surfactant molecules 1401 fully cover both the surface of the first metallic material 1103 and the surface of the second metallic material 1105. The surfactant molecules 1401 are adsorbed on the surface of the first metallic material 1103 through nitrogen-based functional groups (such as, for example, nitrogen-based functional groups 711 illustrated in FIG. 7C). The surfactant molecules 1401 are adsorbed on the surface of the second metallic material 1105 through unsaturated carbon functional groups (such as, for example, unsaturated carbon functional groups 703 illustrated in FIG. 7C). In some embodiments, the adsorbed surfactant molecules 1401 form a surfactant layer on the surface of the metallic layer 1101.

Referring to FIGS. 3A, 4 and 15, in step 307, a barrier layer 1501 is formed in the openings 209 and 211, and over the IMD layer 207₁. The barrier layer 1501 may comprise titanium, titanium nitride, tantalum, tantalum nitride, a combination thereof, a multilayer thereof, or the like. In some embodiments, the barrier layer 1501 is deposited using an ALD process. The surfactant soaking process described above with reference to FIG. 6 alters an ALD deposition rate of the barrier layer 1501 over the top surfaces of the contact plugs 115 and 117. In some embodiments, the surfactant soaking process suppresses the ALD deposition rate of the barrier layer 1501 over the surfactant layer 601, such that the barrier layer 1501 is deposited on the exposed surfaces of the IMD layer 207₁ and is not deposited over the top surfaces of the contact plugs 115 and 117. In some embodiments, the barrier layer 1501 may be formed using a deposition module 407 of the apparatus 400. In such embodiments, the structure of the FIG. 6 is transferred from the soaking modules 403 or 405 to the deposition module 407. In some embodiments, the barrier layer 1501 has a thickness between about 0 Å and about 20 Å.

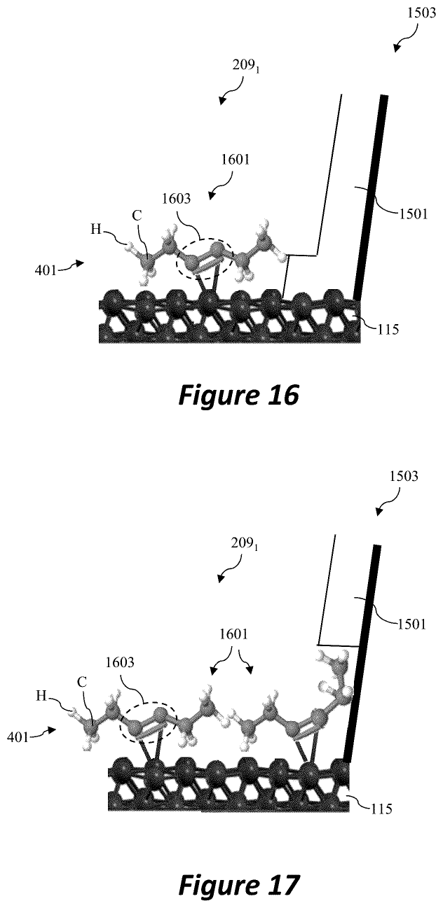

FIG. 16 illustrates a magnified view of a region 1503 of the structure shown in FIG. 15 in accordance with some embodiments. In some embodiments when the surfactant molecules are alkyne molecules 1601, the alkyne molecules 1601 are bonded to a conductive material of the contact plug 115 through alkyne moieties 1603. In some embodiments, the alkyne moieties 1603 of the alkyne molecules 1601 are bonded to conductive material of the contact plug 115 by coordinate covalent bonds. In some embodiments, the alkyne molecules 1601 are bonded to the exposed surface of the contact plug 115 such that no alkyne molecule is bonded at corners of the via opening 209₁. In such embodiments, the barrier layer 1501 is deposited such that the barrier layer 1501 fully covers sidewalls of the via opening 209₁ and physically contacts the top surface of the contact plug 115. In some embodiments, the barrier layer 1501 may partially extend along the top surface of the contact plug 115.

FIG. 17 illustrates a magnified view of the region 1503 of the structure shown in FIG. 15 in accordance with some embodiments. In some embodiments when the surfactant molecules are alkyne molecules 1601, the alkyne molecules 1601 are bonded to a conductive material of the contact plug 115 through alkyne moieties 1603. In some embodiments, the alkyne moieties 1603 of the alkyne molecules 1601 are bonded to conductive material of the contact plug 115 by coordinate covalent bonds. In some embodiments, the alkyne molecules 1601 are bonded to the exposed surface of the contact plug 115 such that the alkyne molecules 1601 cover corners of the via opening 209₁. In such embodiments, the barrier layer 1501 is deposited such that the barrier layer 1501 partial covers the sidewalls of the via opening 209₁ and does not cover the corners of the via opening 209₁ due to the steric hindrance effect. In some embodiments, the barrier layer 1501 is not in physical contact with the top surface of the contact plug 115.

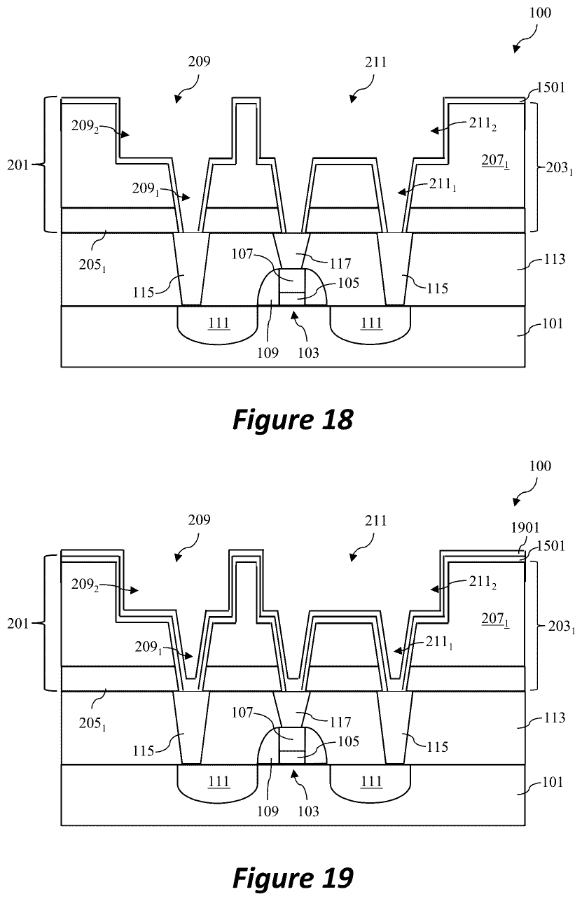

Referring to FIG. 18, in some embodiments, after forming the barrier layer 1501, a plasma process is performed on the barrier layer 1501 to densify the material of the barrier layer 1501. In some embodiments, the plasma process is an H₂ plasma process. In some embodiments, the H₂ plasma process further removes the surfactant layer 601 (see FIG. 15) and exposes the top surfaces of the contact plugs 115 and 117.

Referring to FIG. 19, an adhesion layer 1901 is formed over the barrier layer 1501 within the openings 209 and 211, and over the IMD layer 207₁. The adhesion layer 1901 may comprise cobalt, ruthenium, an alloy thereof, a combination thereof, a multilayer thereof, or the like, and may be formed by ALD, CVD, PVD, sputtering, a combination thereof, or the like. In some embodiments, the adhesion layer 1901 may comprise a layer of cobalt, a layer of ruthenium, or a multi-layer comprising a layer of cobalt and a layer of ruthenium. The adhesion layer 1901 extends along the surfaces of the contact plugs 115 and 117. In some embodiments, the adhesion layer 1901 has a thickness between about 0 Å and about 40 Å.

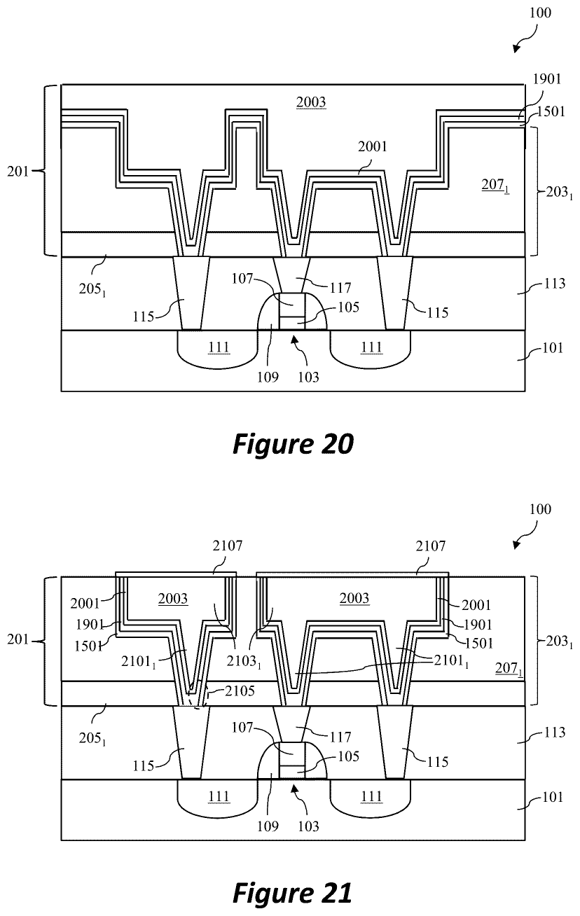

Referring to FIG. 20, a seed layer 2001 is formed over the adhesion layer 1901 within the openings 209 and 211, and over the IMD layers 207₁. The seed layer 2001 may comprise copper, titanium, nickel, gold, manganese, a combination thereof, a multilayer thereof, or the like, and may be formed by ALD, CVD, PVD, sputtering, a combination thereof, or the like. Subsequently, a conductive layer 2003 is formed over the seed layer 2001 within the openings 209 and 211, and over the IMD layers 207₁. In some embodiments, the conductive layer 2003 overfills the openings 209 and 211. The conductive layer 2003 may comprise copper, aluminum, tungsten, ruthenium, cobalt, combinations thereof, alloys thereof, multilayers thereof, or the like, and may be formed using, for example, plating, or other suitable methods. In some embodiments, the seed layer 2001 has a thickness between about 0 Å and about 200 Å.

Referring to FIG. 21, portions of the barrier layer 1501, the adhesion layer 1901, the seed layer 2001, and the conductive layer 2003 overfilling the openings 209 and 211 (see, for example, FIG. 2) are removed to expose a top surface of the IMD layer 207₁. In some embodiments, the removal process may be a planarization process comprising a CMP process, a grinding process, an etching process, a combination thereof, or the like. Remaining portions of the barrier layer 1501, the adhesion layer 1901, the seed layer 2001, and the conductive layer 2003 filling the via openings 209₁ and 211₁ (see, for example, FIG. 2) form conductive vias 2101₁, and remaining portions of the barrier layer 1501, the adhesion layer 1901, the seed layer 2001, and the conductive layer 2003 filling the line openings 2092 and 2112 (see, for example, FIG. 2) form conductive lines 2103₁. In some embodiments, topmost surfaces of the conductive lines 2103₁ are substantially coplanar or level with a topmost surface of the IMD layer 207₁ within process variations of the planarization process.

In some embodiments when the conductive layer 2003 comprises copper, capping layers 2107 may be selectively formed over the conductive lines 11031. The capping layers 2107 may comprise cobalt, ruthenium, an alloy thereof, a combination thereof, a multilayer thereof, or the like, and may be formed by ALD, CVD, PVD, sputtering, a combination thereof, or the like. In some embodiments, each of the capping layers 2107 may comprise a layer of cobalt, a layer of ruthenium, or a multi-layer comprising a layer of cobalt and a layer of ruthenium. In some embodiments, the capping layers 2107 have a thickness between about 0 Å and about 50 Å.

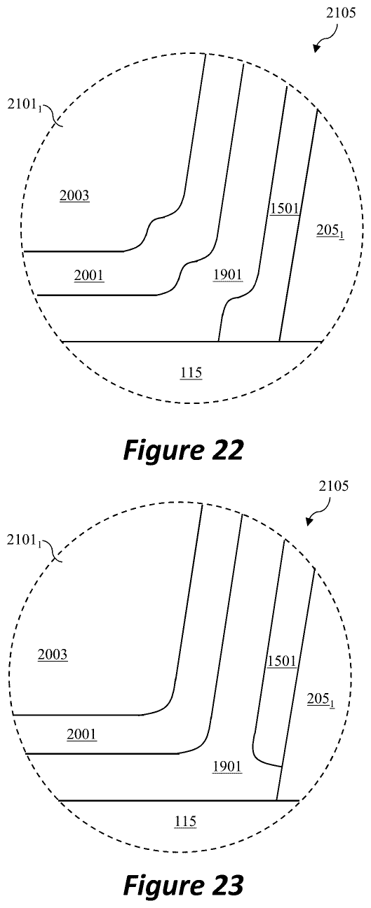

FIG. 22 illustrates a magnified view of a region 2105 of the structure shown in FIG. 21 in accordance with some embodiments. In the illustrated embodiment, the barrier layer 1501 is deposited such that the barrier layer 1501 fully covers and is in physical contact with sidewalls of the ESL 205₁, and is in physically contact with the top surface of the contact plug 115. The barrier layer 1501 does not extend along the top surface of the contact plug 115, but covers corners formed by the sidewalls of the ESL 205₁ and the top surface of the contact plug 115. In the illustrated embodiment, the adhesion layer 1901 extends along and is in physical contact with the top surface of the contact plug 115. By selectively depositing the barrier layer 1501 in the openings 209 and 211 (see, for example, FIG. 2), an amount (or volume) of the barrier layer 1501 within the openings 209 and 211 is reduced. As a result, a contact resistance between the conductive vias 2101₁ and respective ones of the contact plugs 115 and 117 (see FIG. 21) is reduced.

FIG. 23 illustrates a magnified view of the region 2105 of the structure shown in FIG. 21 in accordance with some embodiments. In the illustrated embodiment, the barrier layer 1501 is deposited such that the barrier layer 1501 partially covers and is in physical contact with sidewalls of the ESL 205₁, does not extend along the top surface of the contact plug 115, and does not cover corners formed by the sidewalls of the ESL 205₁ and the top surface of the contact plug 115. In some embodiments, the adhesion layer 1901 covers corners formed by the sidewalls of the ESL 205₁ and the top surface of the contact plug 115, is in physical contact with the sidewalls of the ESL 205₁, and extends along and is in physical contact with the top surface of the contact plug 115. By selectively depositing the barrier layer 1501 in the openings 209 and 211 (see, for example, FIG. 2), an amount (or volume) of the barrier layer 1501 within the openings 209 and 211 is reduced. As a result, a contact resistance between the conductive vias 2101₁ and respective ones of the contact plugs 115 and 117 (see FIG. 21) is reduced.

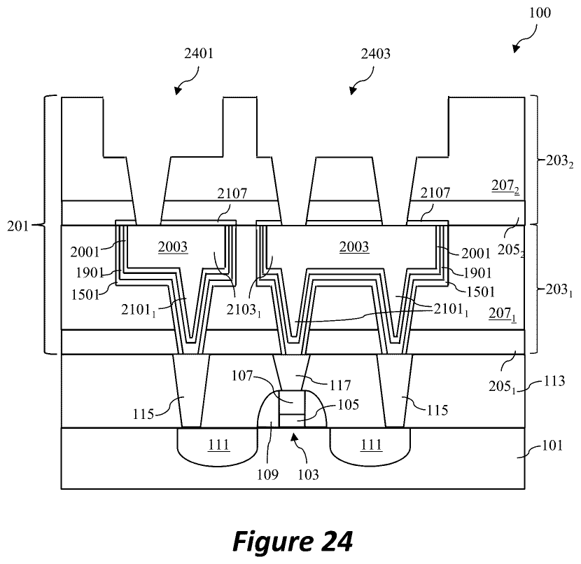

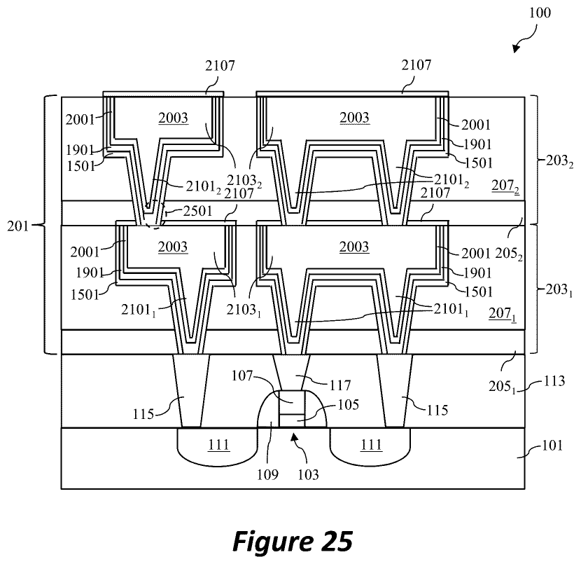

FIGS. 24 and 25 illustrate formation of a metallization layer 203₂ over the metallization layer 203₁. Referring to FIG. 24, in some embodiments, process steps for forming the metallization layer 203₂ start with forming an ESL 205₂ over the metallization layer 203₁. In some embodiments, the ESL 205₂ is formed using similar materials and methods as the ESL 205₁ described above with reference to FIG. 2, and the description is not repeated herein. Subsequently, an IMD layer 207₂ is formed over the ESL 205₂. In some embodiments, the IMD layer 207₂ is formed using similar materials and methods as the IMD layer 207₁ described above with reference to FIG. 2, and the description is not repeated herein.

In some embodiments, the IMD layer 207₂ and the ESL 205₂ are patterned to form opening 2401 and 2403 therein. In some embodiments, the opening 2401 and 2403 are formed in a similar manner as the openings 209 and 211 described above with reference to FIG. 2, and the description is not repeated herein. In some embodiments, the pattering process also removes portions of the capping layers 2107 exposed by the openings 2401 and 2403. In some embodiments, the portions of the capping layers 2107 exposed by the openings 2401 and 2403 are fully removed, such that the openings 2401 and 2403 expose the material of the conductive layer 2003. In other embodiments, the portions of the capping layers 2107 exposed by the opening 2401 and 2403 are partially removed, such that the openings 2401 and 2403 expose the material of the conductive layer 2003 and the material of the capping layers 2107. In some embodiments, exposed top portion of the conductive line 2103₁ comprises two or more metallic materials and has a structure similar to the metallic layer 1101 illustrated in FIGS. 11A, 11B, 12A, 12B, 13, and 14.

Referring to FIG. 25, interconnects, such as conductive vias 2101₂ and conductive lines 2103₂, are formed in the openings 2401 and 2402 (see FIG. 24). In some embodiments, the conductive vias 2101₂ and the conductive lines 2103₂ may have similar structures as the conductive vias 2101₁ and the conductive lines 2103₁, with similar features being labeled by similar numerical references.

In some embodiments when the portions of the capping layers 2107 exposed by the openings 2401 and 2403 are fully removed, the conductive vias 2101₂ and the conductive lines 2103₂ may be formed by: performing an oxide reduction process according to step 303 of the method 300 (see FIGS. 3A and 5), performing a surfactant soaking process according the method 305 (see FIGS. 3B and 6), with step 311 being omitted, forming the barrier layer 1501 according to process steps described above with reference to FIG. 15, and forming adhesion layer 1901, the seed layer 2001, the conductive layer 2003, and the capping layers 2107 according to process steps described above with reference to FIGS. 18-21, and the description is not repeated herein.

In some embodiments when the portions of the capping layers 2107 exposed by the openings 2401 and 2403 are partially removed, the conductive vias 1101₂ and the conductive lines 1103₂ may be formed by: performing an oxide reduction process according to step 303 of the method 300 (see FIGS. 3A and 5), performing a surfactant soaking process, forming the barrier layer 1501 according to process steps described above with reference to FIG. 15, and forming adhesion layer 1901, the seed layer 2001, the conductive layer 2003, and the capping layers 2107 according to process steps described above with reference to FIGS. 18-21, and the description is not repeated herein. In some embodiments, the surfactant soaking process is performed according to the method 305 as described above with reference to FIGS. 3B, 4, 11A, and 11B, and the description is not repeated herein. In some embodiments, the surfactant soaking process is performed according to the method 305 as described above with reference to FIGS. 3B, 4, 12A, and 12B, and the description is not repeated herein. In some embodiments, the surfactant soaking process is performed according to the method 305 as described above with reference to FIGS. 3C, 4, and 13, and the description is not repeated herein. In some embodiments, the surfactant soaking process is performed according to the method 305 as described above with reference to FIGS. 3B, 4, and 14, and the description is not repeated herein.

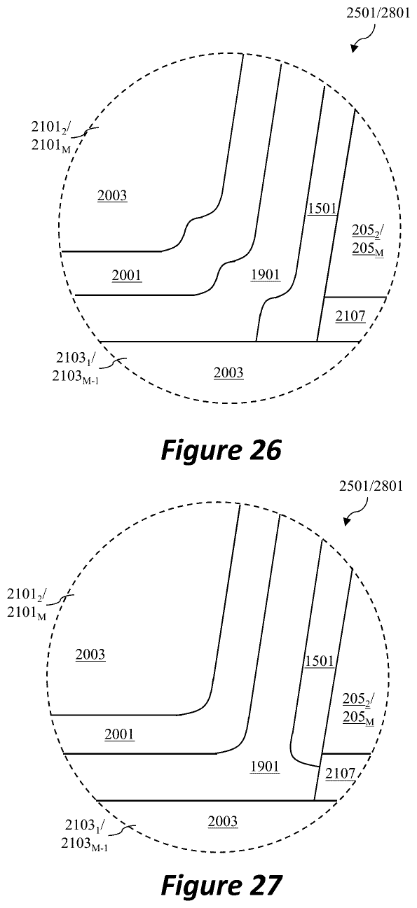

FIG. 26 illustrates a magnified view of a region 2501 of the structure shown in FIG. 25 in accordance with some embodiments. In the illustrated embodiment, the barrier layer 1501 is deposited such that the barrier layer 1501 fully covers and is in physical contact with sidewalls of the ESL 205₂ and the capping layer 2107, and is in physically contact with the top surface of the conductive layer 2003 of the conductive line 2103₁. The barrier layer 1501 does not extend along the top surface of the conductive layer 2003 of the conductive line 2103₁, but covers corners formed by the sidewalls of the capping layer 2107 and the top surface of the conductive layer 2003 of the conductive line 2103₁. In the illustrated embodiment, the adhesion layer 1901 extends along and is in physical contact with the top surface of the conductive layer 2003 of the conductive line 2103₁. By selectively depositing the barrier layer 1501 in the openings within the ESL 205₂ and the IMD layer 207₂, an amount (or volume) of the barrier layer 1501 within the openings is reduced. As a result, a contact resistance between the conductive vias 2101₂ and respective conductive lines 2103₁ is reduced.

FIG. 27 illustrates a magnified view of the region 2501 of the structure shown in FIG. 25 in accordance with some embodiments. In the illustrated embodiment, the barrier layer 1501 is deposited such that the barrier layer 1501 does not extend along the top surface of the conductive layer 2003 of the conductive line 2103₁, fully covers and is in physical contact with sidewalls of the ESL 205₂, partially covers and is in physical contact with sidewalls of the capping layer 2107, and does not cover corners formed by the sidewalls of the capping layer 2107 and the top surface of the conductive layer 2003 of the conductive line 2103₁. In some embodiments, the adhesion layer 1901 covers corners formed by the sidewalls of the capping layer 2107 and the top surface of the conductive layer 2003 of the conductive line 2103₁, is in physical contact with the sidewalls of the capping layer 2107, and extends along and is in physical contact with the top surface of the conductive layer 2003 of the conductive line 2103₁. By selectively depositing the barrier layer 1501 in the openings within the ESL 205₂ and the IMD layer 207₂, an amount (or volume) of the barrier layer 1501 within the openings is reduced. As a result, a contact resistance between the conductive vias 2101₂ and respective conductive lines 2103₁ is reduced.

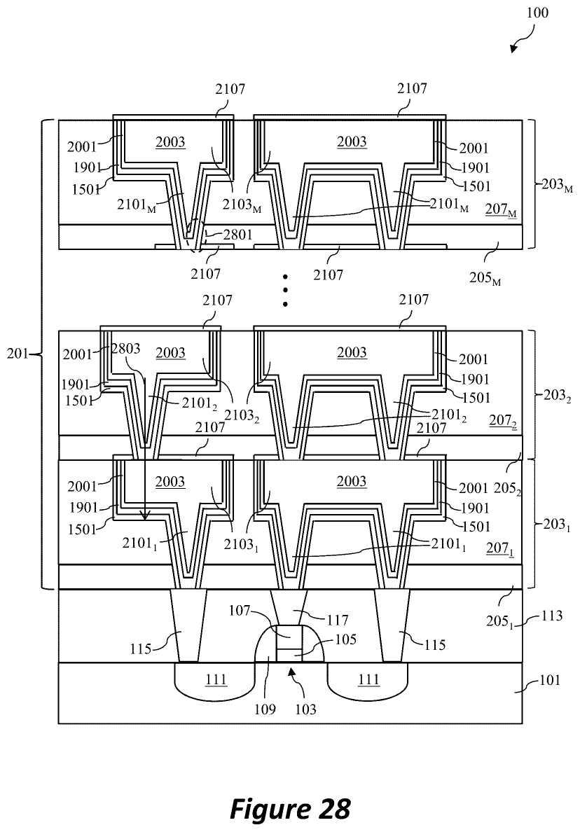

Referring to FIG. 28, one or more metallization layers are formed over the metallization layer 203₂, until a metallization layer 203_{M} is formed. In some embodiments, the metallization layer 203_{M} is the final metallization layer of the interconnect structure 201. In some embodiments, M may be between 1 and 5. In some embodiments, the intermediated metallization layers between the metallization layer 203₂ and the metallization layer 203_{M} are formed in a similar manner as the metallization layer 203₁ and the description is not repeated herein. In other embodiments, the metallization layer 203_{M} is not the final metallization layer of the interconnect structure 201 and additional metallization layers are formed over the metallization layer 203_{M}.

In some embodiments, process steps for forming the metallization layer 203_{M} start with forming an ESL 205_{M} over a previous metallization layer. In some embodiments, the ESL 205_{M} is formed using similar materials and methods as the ESL 205₁ described above with reference to FIG. 2, and the description is not repeated herein. Subsequently, an IMD layer 207_{M} is formed over the ESL 205_{M}. In some embodiments, the IMD layer 207_{M} is formed using similar materials and methods as the IMD layer 207₁ described above with reference to FIG. 2, and the description is not repeated herein.

In some embodiments, interconnects, such as conductive vias 1101_{M} and conductive lines 1103_{M}, are formed in the IMD layer 207_{M} and the ESL 205_{M}. In some embodiments, the conductive vias 1101_{M} and the conductive lines 1103_{M} may have similar structures as the conductive vias 1101₂ and the conductive lines 1103₂, with similar features being labeled by similar numerical references. In some embodiments, the conductive vias 1101_{M} and the conductive lines 1103_{M} may be formed using process steps as described above with reference to FIGS. 24 and 25, and the description is not repeated herein.

Referring back to FIG. 26, a magnified view of a region 2801 of the structure shown in FIG. 28 is illustrated in accordance with some embodiments. In the illustrated embodiment, the barrier layer 1501 is deposited such that the barrier layer 1501 fully covers and is in physical contact with sidewalls of the ESL 205_{M} and the capping layer 2107, and is in physically contact with the top surface of the conductive layer 2003 of the conductive line 2103_{M-1}. The barrier layer 1501 does not extend along the top surface of the conductive layer 2003 of the conductive line 2103_{M-1}, but covers corners formed by the sidewalls of the capping layer 2107 and the top surface of the conductive layer 2003 of the conductive line 2103_{M-1}. In the illustrated embodiment, the adhesion layer 1901 extends along and is in physical contact with the top surface of the conductive layer 2003 of the conductive line 2103_{M-1}. By selectively depositing the barrier layer 1501 in the openings within the ESL 205_{M} and the IMD layer 207_{M}, an amount (or volume) of the barrier layer 1501 within the openings is reduced. As a result, a contact resistance between the conductive vias 2101_{M} and respective conductive lines 2103_{M-1} is reduced.

Referring back to FIG. 27, a magnified view of the region 2801 of the structure shown in FIG. 28 is illustrated in accordance with some embodiments. In the illustrated embodiment, the barrier layer 1501 is deposited such that the barrier layer 1501 does not extend along the top surface of the conductive layer 2003 of the conductive line 2103_{M-1}, fully covers and is in physical contact with sidewalls of the ESL 205_{M}, partially covers and is in physical contact with sidewalls of the capping layer 2107, and does not cover corners formed by the sidewalls of the capping layer 2107 and the top surface of the conductive layer 2003 of the conductive line 2103_{M-1}. In some embodiments, the adhesion layer 1901 covers corners formed by the sidewalls of the capping layer 2107 and the top surface of the conductive layer 2003 of the conductive line 2103_{M-1}, is in physical contact with the sidewalls of the capping layer 2107, and extends along and is in physical contact with the top surface of the conductive layer 2003 of the conductive line 2103_{M-1}. By selectively depositing the barrier layer 1501 in the openings within the ESL 205_{M} and the IMD layer 207_{M}, an amount (or volume) of the barrier layer 1501 within the openings is reduced. As a result, a contact resistance between the conductive vias 2101_{M} and respective conductive lines 2103_{M-1} is reduced.

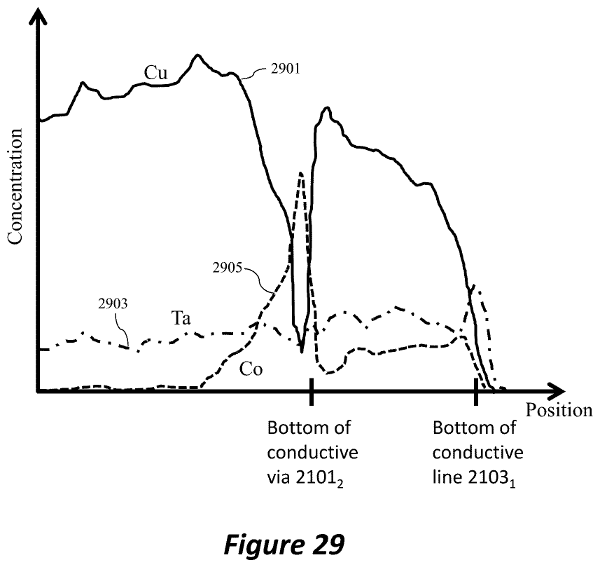

FIG. 29 illustrates concentration profiles of various elements within conductive via 2101₂ and the conductive line 2103₁ in accordance with some embodiments. In the illustrated embodiment, the concentration profiles of various elements are illustrated along a line 2803 illustrated in FIG. 28. In some embodiments, the concentration profiles may be determined by energy-dispersive X-ray spectroscopy (EDX), electron energy loss spectroscopy (EELS), secondary ion mass spectrometry (SIMS), or the like. In some embodiments when the barrier layer 1501 comprises tantalum nitride, the adhesion layer 1901 comprises cobalt, the seed layer 2001 comprises copper, and the conductive layer 2003 comprises copper, the solid curve 2901 illustrates the concentration profile of copper, the dash-dotted curve 2903 illustrates the concentration profile of tantalum, and the dashed curve 2905 illustrates the concentration profile of cobalt. In some embodiments, the concentration of copper dips at a bottom of the conductive via 2101₂ and at a bottom of the conductive line 2103₁. In some embodiments, the concentration of cobalt reaches a maximal value at the bottom of the conductive via 2101₂. In some embodiments, the concentration of tantalum reaches a maximal value at the bottom of the conductive line 2103₁. In some embodiments, the concentration of tantalum at the bottom of the conductive via 2101₂ is less than the concentration of tantalum at the bottom of the conductive line 2103₁.

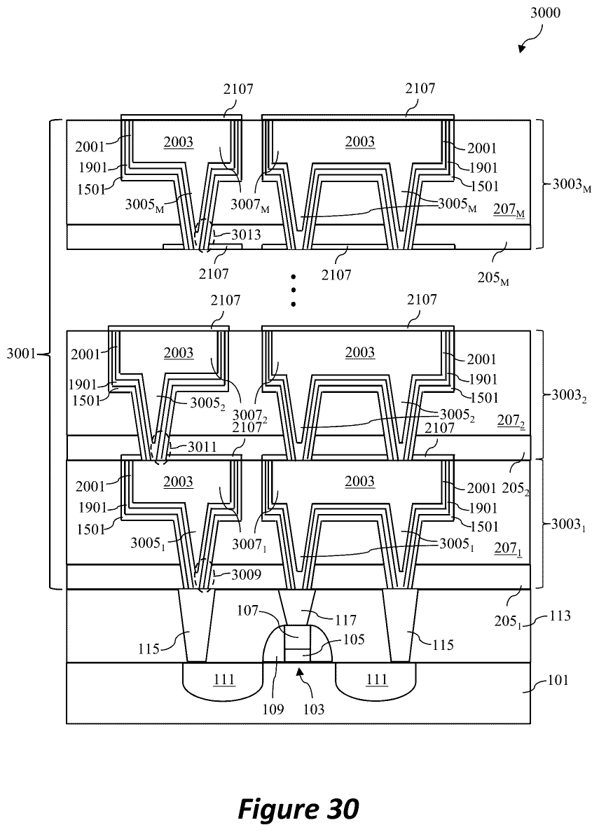

FIG. 30 illustrates a cross-sectional view of a semiconductor device 3000 in accordance with some embodiments. In some embodiments, the semiconductor device 3000 comprises the interconnect structure 3001 having metallization layers 3003₁ to 3003_{M}, such that the metallization layers 3003₁ to 3003_{M} comprise conductive vias 3005₁ to 3005_{M} and conductive lines 3307₁ to 3007_{M}, respectively. The semiconductor device 3000 may be formed in a similar manner as the semiconductor device 100 (see FIG. 28), with similar features being labeled by similar numerical references. In particular, the metallization layers 3003₁ to 3003_{M} including conductive vias 3005₁ to 3005_{M} and conductive lines 3307₁ to 3007_{M} may formed using process steps similar to process steps described above with reference to FIGS. 2, 3A-3C, 4-6, 7A-7C, 8-10, 11A, 11B, 12A, 12B, 13-28. In the illustrated embodiment, the process for removing the surfactant layers 601 (see FIG. 15) as described above with reference to FIG. 18 is performed after forming the adhesion layers 1901. In such embodiments, the surfactant layers 601 suppress the deposition rate of the adhesion layers 1901 over underlying conductive features (such as contact plugs 115 and 117, and conductive lines 3007₁ to 3007_{M}), such that the adhesion layers 1901 are not deposited over the underlying conductive features.

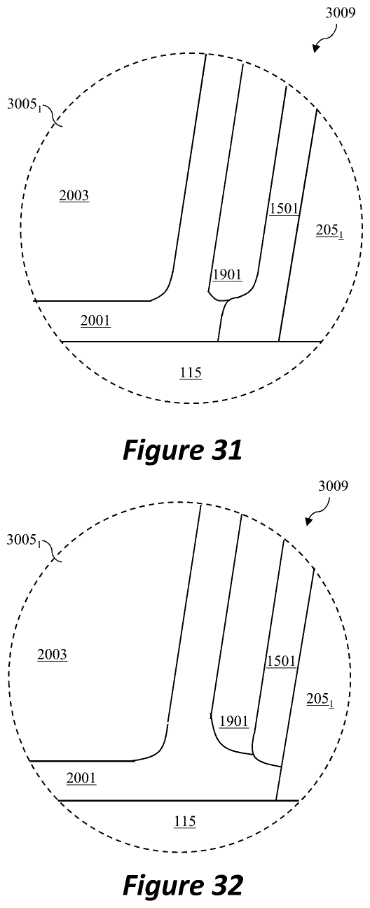

FIG. 31 illustrates a magnified view of a region 3009 of the semiconductor device 3000 (see FIG. 30) in accordance with some embodiments. The region 3009 has a similar structure as the region 2105 illustrated in FIG. 22, with the distinction that the adhesion layer 1901 does not extend along the top surface of the contact plug 115 and is not in physical contact with the top surface of the contact plug 115. In the illustrated embodiment, the seed layer 2001 extends along and is in physical contact with the top surface of the contact plug 115.

FIG. 32 illustrates a magnified view of a region 3009 of the semiconductor device 3000 (see FIG. 30) in accordance with some embodiments. The region 3009 has a similar structure as the region 2105 illustrated in FIG. 23, with the distinction that the adhesion layer 1901 does not extend along the top surface of the contact plug 115, does not cover corners formed by the sidewalls of the ESL 205₁ and the top surface of the contact plug 115, and is not in physical contact with the sidewalls of the ESL 205₁. In the illustrated embodiment, the seed layer 2001 covers corners formed by the sidewalls of the ESL 205₁ and the top surface of the contact plug 115, is in physical contact with the sidewalls of the ESL 205₁, and extends along and is in physical contact with the top surface of the contact plug 115.

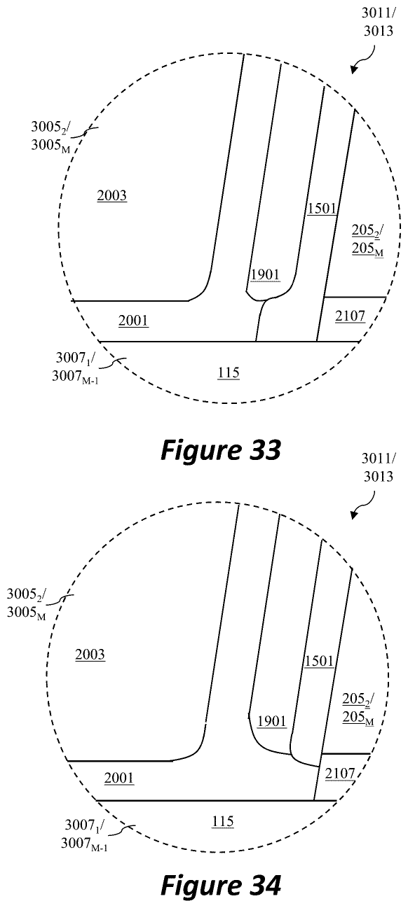

FIG. 33 illustrates magnified views of regions 3011 and 3013 of the semiconductor device 3000 (see FIG. 30) in accordance with some embodiments. The region 3011 has a similar structure as the region 2501 illustrated in FIG. 26, with the distinction that the adhesion layer 1901 does not extend along the top surface of the conductive layer 2003 of the conductive line 3007₁ and is not in physical contact with the top surface of the conductive layer 2003 of the conductive line 3007₁. In the illustrated embodiment, the seed layer 2001 extends along and is in physical contact with the top surface of the conductive layer 2003 of the conductive line 3007₁.

The region 3013 has a similar structure as the region 2801 illustrated in FIG. 26, with the distinction that the adhesion layer 1901 does not extend along the top surface of the conductive layer 2003 of the conductive line 3007_{M-1} and is not in physical contact with the top surface of the conductive layer 2003 of the conductive line 3007_{M-1}. In the illustrated embodiment, the seed layer 2001 extends along and is in physical contact with the top surface of the conductive layer 2003 of the conductive line 3007_{M-1}.

FIG. 34 illustrates magnified views of regions 3011 and 3013 of the semiconductor device 3000 (see FIG. 30) in accordance with some embodiments. The region 3011 has a similar structure as the region 2501 illustrated in FIG. 27, with the distinction that the adhesion layer 1901 does not extend along the top surface of the conductive layer 2003 of the conductive line 3007₁, does not cover corners formed by the sidewalls of the capping layer 2107 and the top surface of the conductive layer 2003 of the conductive line 3007₁, and is not in physical contact with the sidewalls of the capping layer 2107. In the illustrated embodiment, the seed layer 2001 covers corners formed by the sidewalls of the capping layer 2107 and the top surface of the conductive layer 2003 of the conductive line 3007₁, is in physical contact with the sidewalls of the capping layer 2107, and extends along and is in physical contact with the top surface of the conductive layer 2003 of the conductive line 3007₁.

The region 3013 has a similar structure as the region 2801 illustrated in FIG. 27, with the distinction that the adhesion layer 1901 does not extend along the top surface of the conductive layer 2003 of the conductive line 3007_{M-1}, does not cover corners formed by the sidewalls of the capping layer 2107 and the top surface of the conductive layer 2003 of the conductive line 3007_{M-1}, and is not in physical contact with the sidewalls of the capping layer 2107. In the illustrated embodiment, the seed layer 2001 covers corners formed by the sidewalls of the capping layer 2107 and the top surface of the conductive layer 2003 of the conductive line 3007_{M-1}, is in physical contact with the sidewalls of the capping layer 2107, and extends along and is in physical contact with the top surface of the conductive layer 2003 of the conductive line 3007_{M-1}.

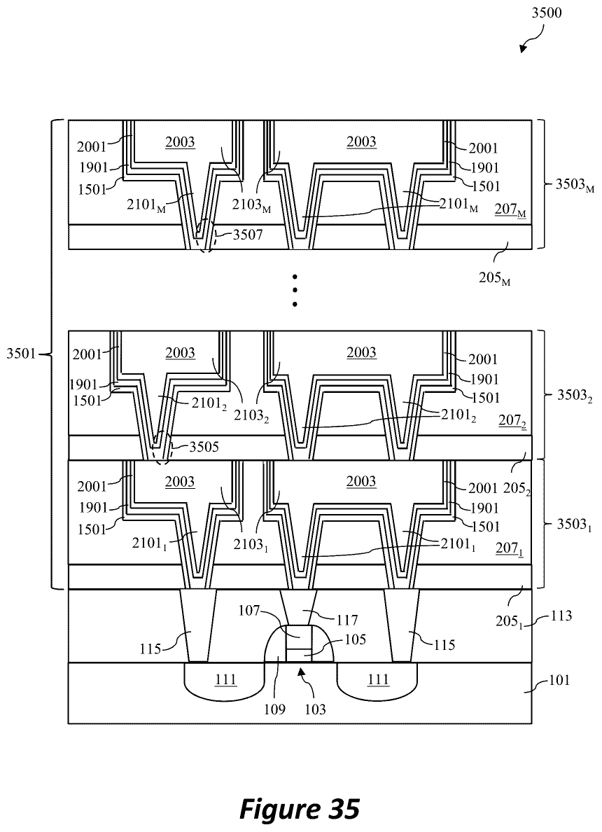

FIG. 35 illustrates a cross-sectional view of a semiconductor device 3500 in accordance with some embodiments. In some embodiments, the semiconductor device 3500 comprises the interconnect structure 3501 having metallization layers 3503₁ to 3503_{M}, such that the metallization layers 3503₁ to 3503_{M} comprise conductive vias 2101₁ to 2101_{M} and conductive lines 2103₁ to 2103_{M}, respectively. The semiconductor device 3500 may be formed in a similar manner as the semiconductor device 100 (see FIG. 28), with similar features being labeled by similar numerical references. In particular, the metallization layers 3503₁ to 3503_{M} including conductive vias 2101₁ to 2101_{M} and conductive lines 2103₁ to 2103_{M} may be formed using process steps similar to process steps described above with reference to FIGS. 2, 3A-3C, 4-6, 7A-7C, 8-10, 11A, 11B, 12A, 12B, 13-28, with the distinction that the formation of the capping layers 2107 has been omitted.

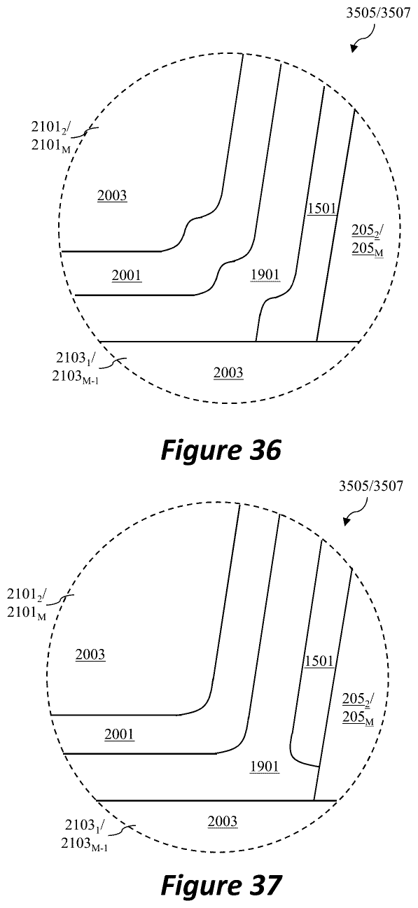

FIG. 36 illustrates magnified views of regions 3505 and 3507 of the semiconductor device 3500 (see FIG. 35) in accordance with some embodiments. The regions 3505 and 3507 have similar structures as the regions 2501 and 2801, respectively (see FIG. 26), with the distinction that the capping layer 2107 has been omitted.

FIG. 37 illustrates magnified views of regions 3505 and 3507 of the semiconductor device 3500 (see FIG. 35) in accordance with some embodiments. The regions 3505 and 3507 have similar structures as the regions 2501 and 2801, respectively (see FIG. 27), with the distinction that the capping layer 2107 has been omitted.

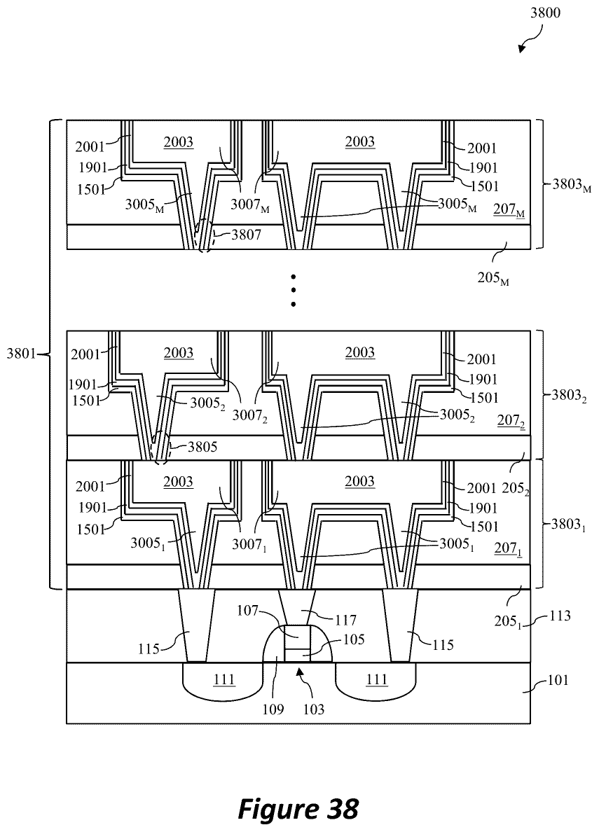

FIG. 38 illustrates a cross-sectional view of a semiconductor device 3800 in accordance with some embodiments. In some embodiments, the semiconductor device 3800 comprises the interconnect structure 3801 having metallization layers 3803₁ to 3803_{M}, such that the metallization layers 3803₁ to 3803_{M} comprise conductive vias 3005₁ to 3005_{M} and conductive lines 3007₁ to 3007_{M}, respectively. The semiconductor device 3800 has a similar structure as the semiconductor device 3000 (see FIG. 30), with similar features being labeled by similar numerical references. In some embodiments, the semiconductor device 3800 may be formed using process steps similar to the process steps for forming the semiconductor device 3000 described above with reference to FIG. 30, with the distinction that the formation of the capping layers 2107 has been omitted.

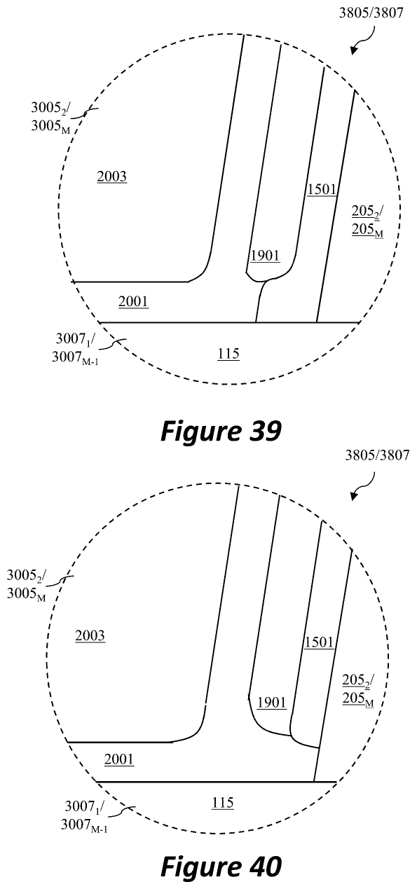

FIG. 39 illustrates magnified views of regions 3805 and 3807 of the semiconductor device 3800 (see FIG. 38) in accordance with some embodiments. The regions 3805 and 3807 have similar structures as the regions 3011 and 3013, respectively (see FIG. 33), with the distinction that the capping layer 2107 has been omitted.

FIG. 40 illustrates magnified views of regions 3805 and 3807 of the semiconductor device 3800 (see FIG. 38) in accordance with some embodiments. The regions 3805 and 3807 have similar structures as the regions 3011 and 3013, respectively (see FIG. 34), with the distinction that the capping layer 2107 has been omitted.

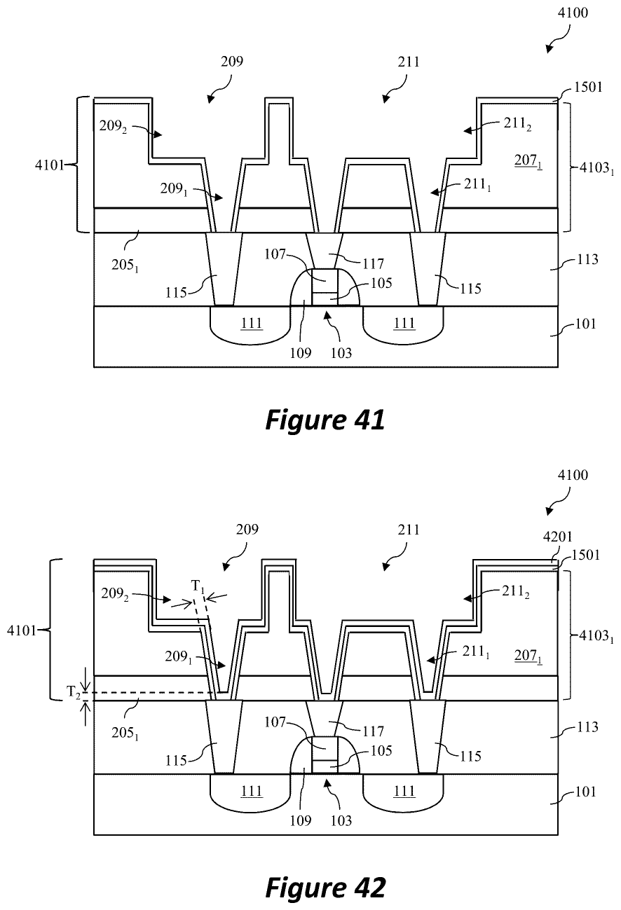

FIGS. 41-49 illustrate cross-sectional views of various intermediate stages of fabrication of a semiconductor device 4100 in accordance with some embodiments. In particular, FIGS. 41-49 illustrate cross-sectional views of various intermediate stages of fabrication of an interconnect structure 4101 over the structure of FIG. 1. Referring to FIG. 41, in some embodiments, the steps for forming the interconnect structure 4101 starts with forming a metallization layer 4103₁ over the one or more ILD layers 113 and the contact plugs 115 and 117. In some embodiments, the formation of the metallization layer 4103₁ starts with forming an ESL 205₁ over the one or more ILD layers 113 and the contact plugs 115 and 117, and forming an IMD layer 207₁ over the ESL 205₁ as described above with reference to FIG. 2, and the description is not repeated herein.

In some embodiments, after forming the IMD layer 207₁, openings 209 and 211 are formed within the IMD layer 207₁ and the ESL 205₁ as described above with reference to FIG. 2, and the description is not repeated herein. Subsequently, a barrier layer 1501 is formed in the openings 209 and 211 as described above with reference to FIGS. 3A-3C, 4-6, 7A-7C, 8-10, 11A, 11B, 12A, 12B, and 13-18, and the description is not repeated herein.

Referring to FIG. 42, a barrier layer 4201 is formed in the openings 209 and 211, and over the barrier layer 1501. The barrier layer 4201 may comprise titanium, titanium nitride, tantalum, tantalum nitride, a combination thereof, a multilayer thereof, or the like. In some embodiments, the barrier layer 1501 and the barrier layer 4201 may comprise a same material. In other embodiments, the barrier layer 1501 and the barrier layer 4201 may comprise different materials. In some embodiments, the barrier layer 4201 has a thickness between about 0 Å and about 20 Å.

In some embodiments, the barrier layer 4201 is deposited along bottoms and sidewalls of the openings 209 and 211 using a deposition method that is unaffected by the surface modification process, which is performed before forming the barrier layer 1501 as described above with reference to FIGS. 3A-3C, 4-6, 7A-3C, 8-10, 11A, 11B, 12A, 12B, 13, and 14. In other embodiments, the barrier layer 4201 is deposited after removing the surfactant layer 601 (see FIG. 15) as described above with reference to FIG. 18. In such embodiments, the barrier layer 4201 is formed over and in physical contact with the exposed top surfaces of the contact plugs 115 and 117. In some embodiments, the barrier layer 4201 may be deposited using PVD, or the like. The barrier layers 1501 and 4201 together may be also referred to as a combined barrier layer. In some embodiments, the combined barrier layer has a thickness T₁ along the sidewalls of the via openings 209₁ and 211₁ and a thickness T₂ along the bottoms of the via openings 209₁ and 211₁. In some embodiments, the thickness T₁ is greater than the thickness T₂. In some embodiments, the thickness T₁ is between about 10 Å and about 30 Å. In some embodiments, the thickness T₂ is between about 1 Å and about 10 Å. In some embodiments, a ratio of the thickness T₁ to the thickness T₂ (T₁/T₂) is between about 1 and about 30.

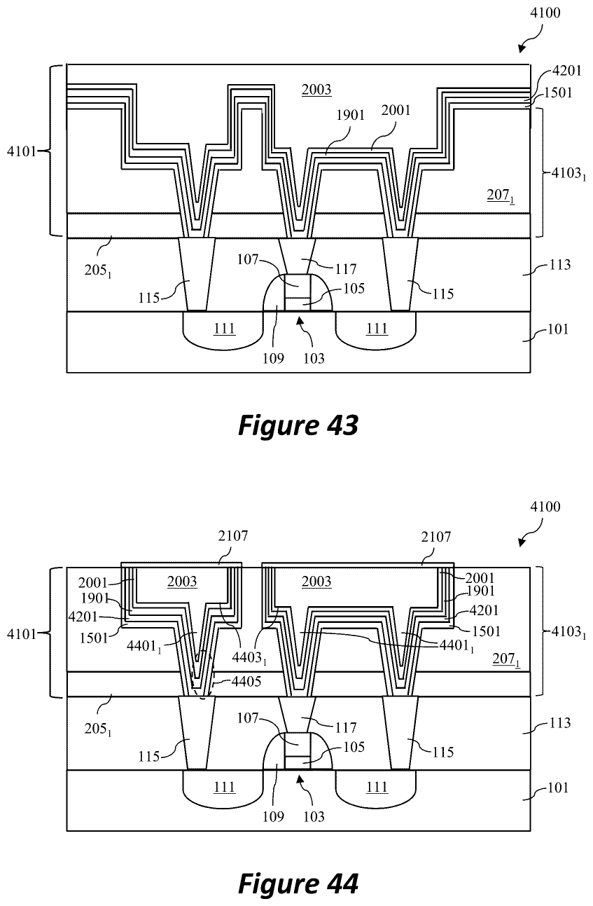

Referring to FIG. 43, after forming the barrier layer 4201, an adhesion layer 1901 is formed in the openings 209 and 211 (see FIG. 41) and over the barrier layer 4201 as described above with reference to FIG. 19, and the description is not repeated herein. Subsequently, a seed layer 2001 is formed in the openings 209 and 211 and over the adhesion layer 1901 as described above with reference to FIG. 20, and the description is not repeated herein. After forming the seed layer 2001, a conductive layer 2003 is formed in the openings 209 and 211 as described above with reference to FIG. 20, and the description is not repeated herein. In some embodiments, the conductive layer 2003 overfills the openings 209 and 211.

Referring to FIG. 44, portions of the barrier layers 1501 and 4201, the adhesion layer 1901, the seed layer 2001, and the conductive layer 2003 overfilling the openings 209 and 211 (see FIG. 41) are removed to expose a top surface of the IMD layer 207₁. In some embodiments, the removal process may be a planarization process comprising a CMP process, a grinding process, an etching process, a combination thereof, or the like. Remaining portions of the barrier layers 1501 and 420₁, the adhesion layer 1901, the seed layer 2001, and the conductive layer 2003 filling the via openings 209₁ and 211₁ (see FIG. 41) form conductive vias 4401₁, and remaining portions of the barrier layers 1501 and 420₁, the adhesion layer 1901, the seed layer 2001, and the conductive layer 2003 filling the line openings 2092 and 2112 (see FIG. 41) form conductive lines 4403₁. In some embodiments, topmost surfaces of the conductive lines 4403₁ are substantially coplanar or level with a topmost surface of the IMD layer 207₁ within process variations of the planarization process. In some embodiments, after performing the planarization process, capping layers 2107 are formed over the conductive lines 4403₁ of the metallization layer 4103₁ as described above with reference to FIG. 21, and the description is not repeated herein.

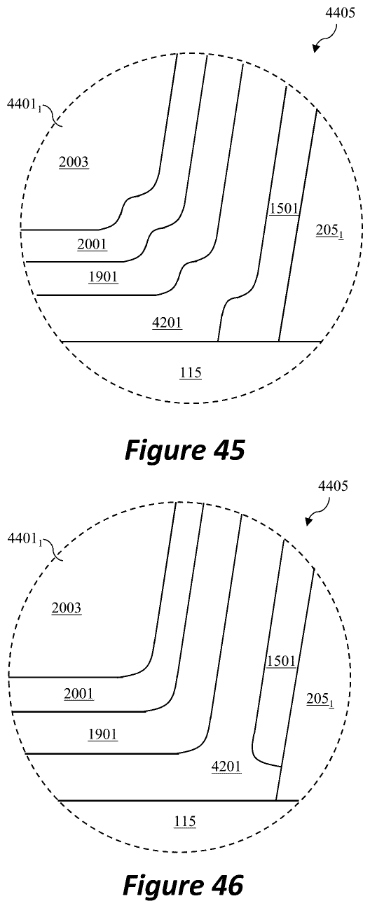

FIG. 45 illustrates a magnified view of a region 4405 of the structure shown in FIG. 44 in accordance with some embodiments. In the illustrated embodiment, the barrier layer 1501 is deposited such that the barrier layer 1501 fully covers and is in physical contact with sidewalls of the ESL 205₁, and is in physically contact with the top surface of the contact plug 115. The barrier layer 1501 does not extend along the top surface of the contact plug 115, but covers corners formed by the sidewalls of the ESL 205₁ and the top surface of the contact plug 115. In the illustrated embodiment, the barrier layer 420₁ extends along and is in physical contact with the top surface of the contact plug 115.

FIG. 46 illustrates a magnified view of the region 4405 of the structure shown in FIG. 44 in accordance with some embodiments. In the illustrated embodiment, the barrier layer 1501 is deposited such that the barrier layer 1501 does not extend along the top surface of the contact plug 115, partially covers and is in physical contact with sidewalls of the ESL 205₁, and does not cover corners formed by the sidewalls of the ESL 205₁ and the top surface of the contact plug 115. In some embodiments, the barrier layer 420₁ covers corners formed by the sidewalls of the ESL 205₁ and the top surface of the contact plug 115, is in physical contact with the sidewalls of the ESL 205₁, and extends along and is in physical contact with the top surface of the contact plug 115.

Referring further to FIGS. 45 and 46, by depositing the barrier layers 1501 and 420₁ in the openings within the ESL 205₁ and the IMD layer 207₁, such that a thickness of the combined barrier layer on the bottoms of the openings is reduced compared to the sidewalls of the openings, an amount (or volume) of the combined barrier layer within the openings is reduced. As a result, a contact resistance between the conductive vias 4401₁ and respective one of the contact plugs 115 and 117 is reduced.

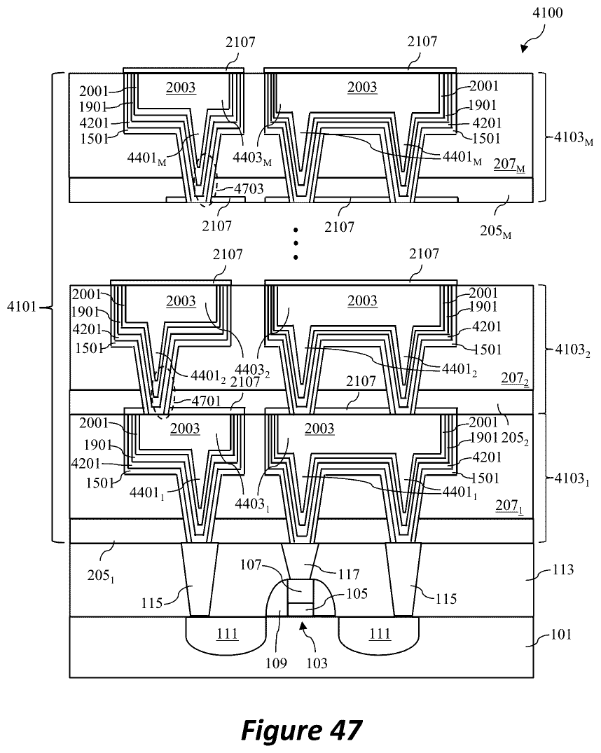

Referring to FIG. 47, a metallization layer 4103₂ is formed over the metallization layer 4103₁. In some embodiments, process steps for forming the metallization layer 4103₂ start with forming an ESL 205₂ over the metallization layer 4103₁ and the capping layers 2107 as described above with reference to FIG. 24, and the description is not repeated herein. Subsequently, an IMD layer 207₂ is formed over the ESL 205₂ as described above with reference to FIG. 24, and the description is not repeated herein.

In some embodiments, interconnects, such as conductive vias 4401₂ and conductive lines 4403₂, are formed in the IMD layer 207₂ and the ESL 205₂. In some embodiments, the conductive vias 4401₂ and the conductive lines 4403₂ may have similar structures as the conductive vias 4401₁ and the conductive lines 4403₁, with similar features being labeled by similar numerical references. In some embodiments, the conductive vias 4401₂ and the conductive lines 4403₂ may be formed using process steps as described above with reference to FIGS. 41-44, and the description is not repeated herein. In some embodiments, the barrier layers 1501 of the metallization layer 4103₂ are formed in a similar manner as the barrier layers 1501 of the metallization layer 203₂ described above with reference to FIG. 25, and the description is not repeated herein.

In some embodiments, after forming the metallization layer 4103₂, one or more metallization layers are formed over the metallization layer 4103₂, until a metallization layer 4103_{M} is formed. In some embodiments, the metallization layer 4103_{M} is the final metallization layer of the interconnect structure 4101. In some embodiments, M may be between 1 and 5. In some embodiments, the intermediated metallization layers between the metallization layer 4103₂ and the metallization layer 4103_{M} are formed in a similar manner as the metallization layer 4103₂ and the description is not repeated herein. In other embodiments, the metallization layer 4103_{M} is not the final metallization layer of the interconnect structure 4101 and additional metallization layers are formed over the metallization layer 4103_{M}.

In some embodiments, process steps for forming the metallization layer 4103_{M} start with an ESL 205_{M} over the previous metallization layer and the capping layers 2107 as described above with reference to FIG. 28, and the description is not repeated herein. Subsequently, an IMD layer 207_{M} is formed over the ESL 205_{M} as described above with reference to FIG. 28, and the description is not repeated herein.

In some embodiments, interconnects, such as conductive vias 4401_{M} and conductive lines 4403_{M}, are formed in the IMD layer 207_{M} and the ESL 205_{M}. In some embodiments, the conductive vias 4401_{M} and the conductive lines 4403_{M} may have similar structures as the conductive vias 4401₁ and the conductive lines 4403₁, with similar features being labeled by similar numerical references. In some embodiments, the conductive vias 4401_{M} and the conductive lines 2203_{M} may be formed using process steps as described above with reference to FIGS. 41-44, and the description is not repeated herein. In some embodiments, the barrier layers 1501 of the metallization layer 4103_{M} are formed in a similar manner as the barrier layers 1501 of the metallization layer 203_{M} described above with reference to FIG. 28, and the description is not repeated herein.

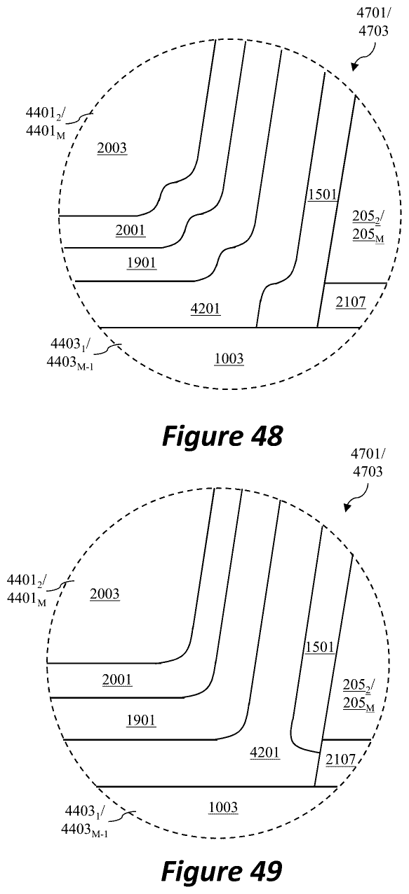

FIG. 48 illustrates magnified views of regions 4701 and 4703 of the semiconductor device 4100 (see FIG. 47) in accordance with some embodiments. Referring first to the region 4701, in the illustrated embodiment, the barrier layer 1501 is deposited such that the barrier layer 1501 does not extend along the top surface of the conductive layer 2003 of the conductive line 4403₁, fully covers and is in physical contact with sidewalls of the ESL 205₂, and partially covers and is in physical contact with sidewalls of the capping layer 2107, and is in physically contact with the top surface of the conductive layer 2003 of the conductive line 4403₁. The barrier layer 1501 covers corners formed by the sidewalls of the capping layer 2107 and the top surface of the conductive layer 2003 of the conductive line 4403₁. In the illustrated embodiment, the barrier layer 420₁ extends along and is in physical contact with the top surface of the conductive layer 2003 of the conductive line 4403₁.

By depositing the barrier layers 1501 and 420₁ in the openings within the ESL 205₂ and the IMD layer 207₂, such that a thickness of the combined barrier layer on the bottoms of the openings is reduced compared to the sidewalls of the openings, an amount (or volume) of the combined barrier layer within the openings is reduced. As a result, a contact resistance between the conductive vias 4401₂ and the respective conductive lines 4403₁ is reduced.

Referring next to the region 4703, in the illustrated embodiment, the barrier layer 1501 is deposited such that the barrier layer 1501 does not extend along the top surface of the conductive layer 2003 of the conductive line 4403_{M-1}, fully covers and is in physical contact with sidewalls of the ESL 205_{M}, and partially covers and is in physical contact with sidewalls of the capping layer 2107, and is in physically contact with the top surface of the conductive layer 2003 of the conductive line 4403_{M-1}. The barrier layer 1501 covers corners formed by the sidewalls of the capping layer 2107 and the top surface of the conductive layer 2003 of the conductive line 4403_{M-1}. In the illustrated embodiment, the barrier layer 420₁ extends along and is in physical contact with the top surface of the conductive layer 2003 of the conductive line 4403_{M-1}.

By depositing the barrier layers 1501 and 420₁ in the openings within the ESL 205_{M} and the IMD layer 207_{M}, such that a thickness of the combined barrier layer on the bottoms of the openings is reduced compared to the sidewalls of the openings, an amount (or volume) of the combined barrier layer within the openings is reduced. As a result, a contact resistance between the conductive vias 4401_{M} and the respective conductive lines 4403_{M-1} is reduced.

FIG. 49 illustrates magnified views of regions 4701 and 4703 of the semiconductor device 4100 (see FIG. 47) in accordance with some embodiments. Referring first to the region 4701, in the illustrated embodiment, the barrier layer 1501 is deposited such the barrier layer 1501 does not extend along the top surface of the conductive layer 2003 of the conductive line 4403₁, covers and is in physical contact with sidewalls of the ESL 205₂, partially covers and is in physical contact with sidewalls of the capping layer 2107, and does not cover corners formed by the sidewalls of the capping layer 2107 and the top surface of the conductive layer 2003 of the conductive line 4403₁. In some embodiments, the barrier layer 420₁ covers corners formed by the sidewalls of the capping layer 2107 and the top surface of the conductive layer 2003 of the conductive line 4403₁, is in physical contact with the sidewalls of the capping layer 2107, and extends along and is in physical contact with the top surface of the conductive layer 2003 of the conductive line 4403₁.

By depositing the barrier layers 1501 and 4201 in the openings within the ESL 205₂ and the IMD layer 207₂, such that a thickness of the combined barrier layer on the bottoms of the openings is reduced compared to the sidewalls of the openings, an amount (or volume) of the combined barrier layer within the openings is reduced. As a result, a contact resistance between the conductive vias 4401₂ and the respective conductive lines 4403₁ is reduced.

Referring next to the region 2503, in the illustrated embodiment, the barrier layer 1501 is deposited such the barrier layer 1501 does not extend along a top surface of the conductive layer 2003 of the conductive line 4403_{M-1}, covers and is in physical contact with sidewalls of the ESL 205_{M}, partially covers and is in physical contact with sidewalls of the capping layer 2107, and does not cover corners formed by the sidewalls of the capping layer 2107 and the top surface of the conductive layer 2003 of the conductive line 4403_{M-1}. In some embodiments, the barrier layer 4201 covers corners formed by the sidewalls of the capping layer 2107 and the top surface of the conductive layer 2003 of the conductive line 4403_{M-1}, is in physical contact with the sidewalls of the capping layer 2107, and extends along and is in physical contact with the top surface of the conductive layer 2003 of the conductive line 4403_{M-1}.

By depositing the barrier layers 1501 and 4201 in the openings within the ESL 205_{M} and the IMD layer 207_{M}, such that a thickness of the combined barrier layer on the bottoms of the openings is reduced compared to the sidewalls of the openings, an amount (or volume) of the combined barrier layer within the openings is reduced. As a result, a contact resistance between the conductive vias 4401_{M} and the respective conductive lines 4403_{M-1} is reduced.

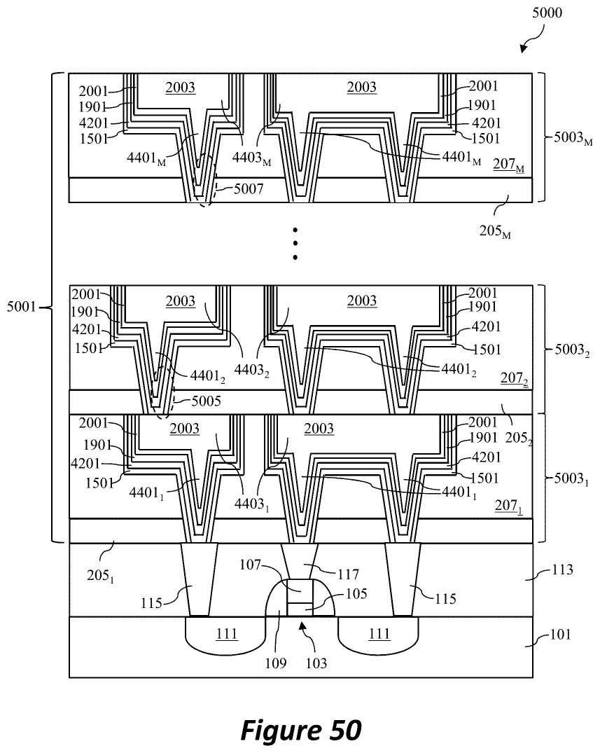

FIG. 50 illustrates a cross-sectional view of a semiconductor device 5000 in accordance with some embodiments. In some embodiments, the semiconductor device 5000 comprises the interconnect structure 5001 having metallization layers 5003₁ to 5003_{M}, such that the metallization layers 5003₁ to 5003_{M} comprise conductive vias 4401₁ to 4401_{M} and conductive lines 4403₁ to 4403_{M}, respectively. The semiconductor device 5000 has a similar structure as the semiconductor device 4100 (see FIG. 47), with similar features being labeled by similar numerical references. In some embodiments, the semiconductor device 5000 may be formed using process steps similar to the process steps for forming the semiconductor device 4100 described above with reference to FIGS. 41-47, with the distinction that the formation of the capping layers 2107 has been omitted.

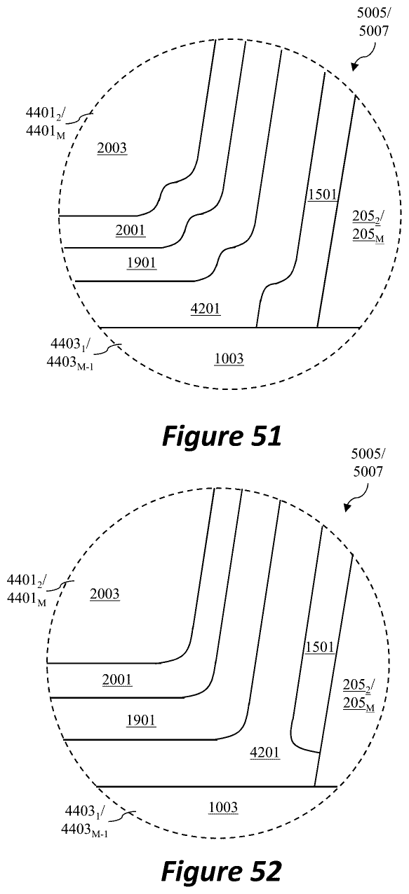

FIG. 51 illustrates magnified views of regions 5005 and 5007 of the semiconductor device 5000 (see FIG. 50) in accordance with some embodiments. The regions 5005 and 5007 have similar structures as the regions 4701 and 4703, respectively (see FIG. 48), with the distinction that the capping layer 2107 has been omitted. In the illustrated embodiment, the barrier layers 1501 fully covers the sidewalls of the ESL 205₂ in the region 5005 and the sidewalls of the ESL 205_{M} in the region 5007.

FIG. 52 illustrates magnified view of regions 5005 and 5007 of the semiconductor device 5000 (see FIG. 50) in accordance with some embodiments. The regions 5005 and 5007 have similar structures as the regions 4701 and 4703, respectively (see FIG. 49), with the distinction that the capping layer 2107 has been omitted. In the illustrated embodiment, the barrier layer 4201 is in physical contact with the sidewalls of the ESL 205₂ in the region 5005 and the sidewalls of the ESL 205_{M} in the region 5007.

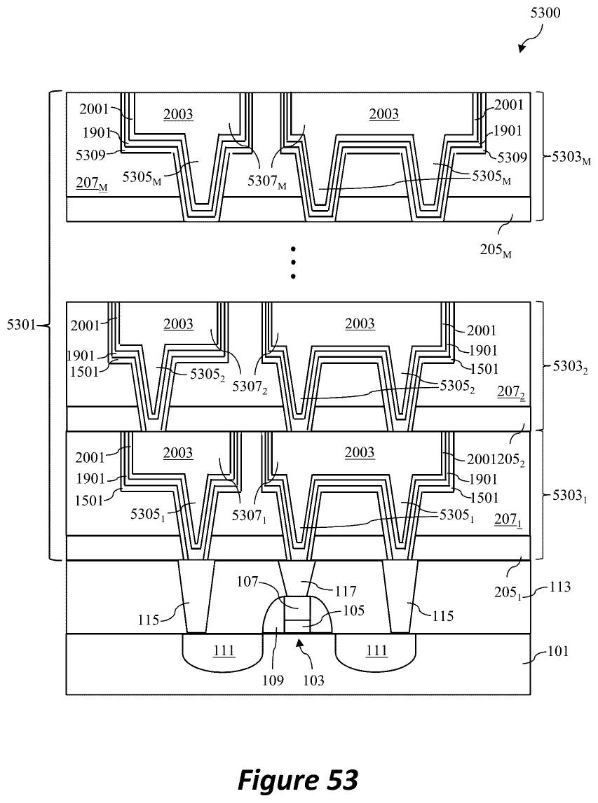

Referring further to FIGS. 28, 30, 35, 38, 47 and 50, the interconnect structures 201, 3001, 3501, 3801, 4101, and 5001, respectively, are formed such that all of the interconnects (such as conductive vias and conductive lines) within each of the interconnect structures have similar structures and are formed using similar process steps. In other embodiments, different interconnects within the interconnect structure may have different structures and may be formed using different process steps. Such embodiments are described below with reference to FIGS. 53-56.

FIG. 53 illustrates a cross-sectional view of a semiconductor device 5300 in accordance with some embodiments. In some embodiments, the semiconductor device 5300 is similar to the semiconductor device 3500 illustrated in FIG. 35, with similar features being labeled with similar numerical references, and the descriptions of the similar features are not repeated herein. In some embodiments, the interconnect structure 5301 of the semiconductor device 5300 is similar to the interconnect structure 3501 of the semiconductor device 3500 (see FIG. 35), with similar features being labeled with similar numerical references, and the descriptions of the similar features are not repeated herein. The interconnect structure 5301 comprises a plurality of metallization layer 5303₁ to 5303_{M}. In some embodiments, the metallization layer 5303_{M} is the final metallization layer of the interconnect structure 5301. In some embodiments, M may be between 1 and 5. In other embodiments, the metallization layer 5303_{M} is not the final metallization layer of the interconnect structure 5301 and additional metallization layers are formed over the metallization layer 5303_{M}.

In the illustrated embodiment, interconnects within different metallization layers of the interconnect structure 5301 have different structures. In particular, interconnects with different sizes may have different structures and may be formed using different process steps. In some embodiments, the metallization layer 5303₁ of the interconnect structure 5301 comprises conductive vias 5305₁ and conductive lines 5307₁. In some embodiments when a width of the conductive vias 5305₁ at the bottom of the conductive vias 5305₁ is between about 5 nm and about 10 nm, the conductive vias 5305₁ and conductive lines 5307₁ may be formed using process steps similar to process steps for forming the conductive vias 2101₁ and conductive lines 2103₁ described above with reference to FIGS. 2, 3A-3C, 4-6, 7A-7C, 8-10, 11A, 11B, 12A, 12B, 13-21, and the description is not repeated herein. In such embodiments, the metallization layer 5303₁ is similar to the metallization layer 3501₁ (see FIG. 35).

In some embodiments, the metallization layer 5303₂ of the interconnect structure 5301 comprises conductive vias 5305₂ and conductive lines 5307₂. In some embodiments when a width of the conductive vias 5305₂ at the bottom of the conductive vias 5305₂ is between about 8 nm and about 14 nm, the conductive vias 5305₂ and conductive lines 5307₂ may be formed using process steps similar to process steps for forming the conductive vias 2101₂ and conductive lines 2103₂ described above with reference to FIGS. 24 and 25, and the description is not repeated herein. In such embodiments, the metallization layer 5303₂ is similar to the metallization layer 3503₂ (see FIG. 35). Furthermore, the metallization layer 5303₁ and the metallization layer 5303₂ have interconnects with similar structures.

In some embodiments, the metallization layer 5303_{M} of the interconnect structure 5301 comprises conductive vias 5305_{M} and conductive lines 5307_{M}. In the illustrated embodiment, a width of the conductive vias 5305_{M} is greater than the width of the conductive vias 5305₁ and the width of the conductive vias 5305₂. In some embodiments when a width of the conductive vias 5305_{M} at the bottom of the conductive vias 5305_{M} is between about 15 nm and about 30 nm, the conductive vias 5305_{M} and conductive lines 5307_{M} may be formed using process steps similar to process steps for forming the conductive vias 2101_{M} and conductive lines 2103_{M} described above with reference to FIG. 28, with the distinction that the surface modification process steps described above with reference to FIGS. 3A-3C, 4-6, 7A-7C, 8-10, 11A, 11B, 12A, 12B, 13, and 14 are omitted. In such embodiments, instead of forming the barrier layer 1501, the barrier layer 5309 is formed over and in physical contact with the conductive line of the underlying metallization layer. Accordingly, the metallization layer 5303_{M} and the metallization layer 5303₁ have interconnects with different structures. Furthermore, the metallization layer 5303_{M} and the metallization layer 5303₂ have interconnects with different structures. In some embodiments, the barrier layer 5309 may comprise titanium, titanium nitride, tantalum, tantalum nitride, a combination thereof, a multilayer thereof, or the like, and may be deposited using ALD, CVD, PVD, a combination thereof, or the like.

In some embodiments, interconnects of the metallization layers interposed between the metallization layer 5303₂ and the metallization layer 5303_{M}, may have different structures depending on the size of the interconnects. In some embodiments when widths of vias are between about 5 nm and about 14 nm, interconnects are formed to have structures similar to interconnects (such as the conductive vias 5305₁ and the conductive lines 5307₁) of the metallization layer 5303₁. In some embodiments when widths of vias are between about 15 nm and about 30 nm, interconnects are formed to have structures similar to interconnects (such as the conductive vias 5305_{M} and the conductive lines 5307_{M}) of the metallization layer 5303_{M}.

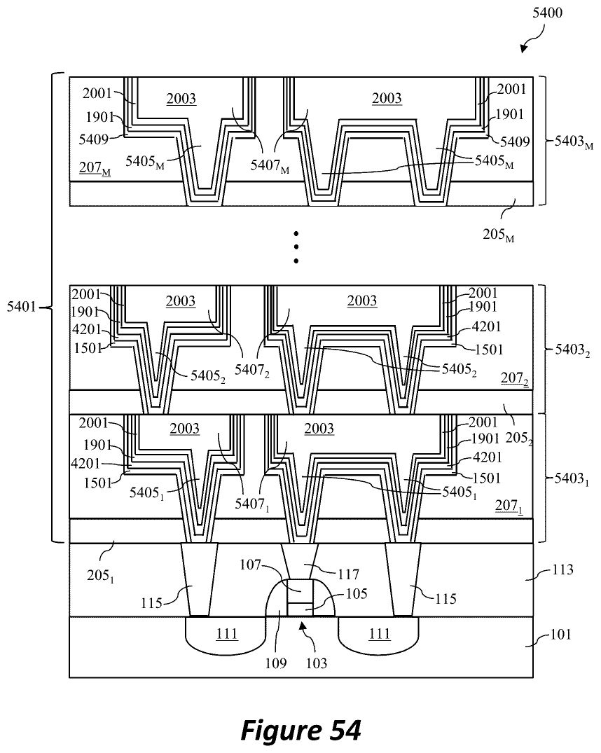

FIG. 54 illustrates a cross-sectional view of a semiconductor device 5400 in accordance with some embodiments. In some embodiments, the semiconductor device 5400 is similar to the semiconductor device 5000 illustrated in FIG. 50, with similar features being labeled with similar numerical references, and the descriptions of the similar features are not repeated herein. In some embodiments, the interconnect structure 5401 of the semiconductor device 5400 is similar to the interconnect structure 5001 of the semiconductor device 5000 (see FIG. 50), with similar features being labeled with similar numerical references, and the descriptions of the similar features are not repeated herein. The interconnect structure 5401 comprises a plurality of metallization layer 5403₁ to 5403_{M}. In some embodiments, the metallization layer 5403_{M} is the final metallization layer of the interconnect structure 5401. In some embodiments, M may be between 1 and 5. In other embodiments, the metallization layer 5403_{M} is not the final metallization layer of the interconnect structure 5401 and additional metallization layers are formed over the metallization layer 5403_{M}.

In the illustrated embodiment, interconnects within different metallization layers of the interconnect structure 5401 have different structures. In particular, interconnects with different sizes may have different structures and may be formed using different process steps. In some embodiments, the metallization layer 5403₁ of the interconnect structure 5401 comprises conductive vias 5405₁ and conductive lines 5407₁. In some embodiments when a width of the conductive vias 5405₁ at the bottom of the conductive vias 5405₁ is between about 6 nm and about 10 nm, the conductive vias 5405₁ and conductive lines 5407₁ may be formed using process steps similar to process steps for forming the conductive vias 4401₁ and conductive lines 4403₁ described above with reference to FIGS. 41-44, and the description is not repeated herein. In such embodiments, the metallization layer 5403₁ is similar to the metallization layer 5003₁ (see FIG. 50).

In some embodiments, the metallization layer 5403₂ of the interconnect structure 5401 comprises conductive vias 5405₂ and conductive lines 5407₂. In some embodiments when a width of the conductive vias 5405₂ at the bottom of the conductive vias 5405₂ is between about 8 nm and about 14 nm, the conductive vias 5405₂ and conductive lines 5407₂ may be formed using process steps similar to process steps for forming the conductive vias 4401₂ and conductive lines 4403₂ described above with reference to FIG. 47, and the description is not repeated herein. In such embodiments, the metallization layer 5403₂ is similar to the metallization layer 5003₂ (see FIG. 50). Furthermore, the metallization layer 5403₁ and the metallization layer 5403₂ have interconnects with similar structures.

In some embodiments, the metallization layer 5403_{M} of the interconnect structure 5401 comprises conductive vias 5405_{M} and conductive lines 5407_{M}. In the illustrated embodiment, a width of the conductive vias 5405 is greater than the width of the conductive vias 5405₁ and the width of the conductive vias 5405₂. In some embodiments when a width of the conductive vias 5405_{M} at the bottom of the conductive vias 5405_{M} is between about 15 nm and about 30 nm, the conductive vias 5405_{M} and conductive lines 5407_{M} may be formed using process steps similar to the process steps for forming the conductive vias 2101_{M} and conductive lines 2103_{M} described above with reference to FIG. 28, with the distinction that the surface modification process steps described above with reference to FIGS. 3A-3C, 4-6, 7A-7C, 8-10, 11A, 11B, 12A, 12B, 13, and 14 are omitted. In such embodiments, instead of forming the barrier layer 1501, the barrier layer 5409 is formed over and in physical contact with the conductive line of the underlying metallization layer. Accordingly, the metallization layer 5403_{M} and the metallization layer 5403₁ have interconnects with different structures. Furthermore, the metallization layer 5403_{M} and the metallization layer 5403₂ have interconnects with different structures. In some embodiments, the barrier layer 5409 may comprise titanium, titanium nitride, tantalum, tantalum nitride, a combination thereof, a multilayer thereof, or the like, and may be deposited using ALD, CVD, PVD, a combination thereof, or the like.

In some embodiments, interconnects of the metallization layers interposed between the metallization layer 5403₂ and the metallization layer 5403_{M}, may have different structures depending on the size of the interconnects. In some embodiments when widths of vias are between about 6 nm and about 14 nm, interconnects are formed to have structures similar to interconnects (such as the conductive vias 5405₁ and the conductive lines 5407₁) of the metallization layer 5403₁. In some embodiments when widths of vias are between about 15 nm and about 30 nm, interconnects are formed to have structures similar to interconnects (the conductive vias 5405_{M} and the conductive lines 5407_{M}) of the metallization layer 5403_{M}.

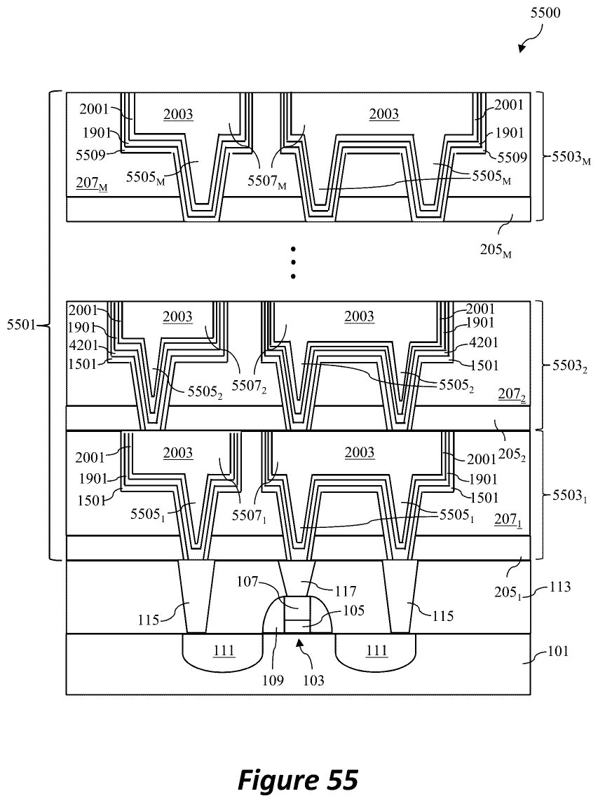

FIG. 55 illustrates a cross-sectional view of a semiconductor device 5500 in accordance with some embodiments. In some embodiments, the semiconductor device 5500 is similar to the semiconductor devices 3500 and 5000 illustrated in FIGS. 35 and 50, respectively, with similar features being labeled with similar numerical references, and the descriptions of the similar features are not repeated herein. In some embodiments, the interconnect structure 5501 of the semiconductor device 5500 is similar to the interconnect structures 3501 and 5001 of the semiconductor device 3500 and 5000, respectively (see FIGS. 35 and 50), with similar features being labeled with similar numerical references, and the descriptions of the similar features are not repeated herein. The interconnect structure 5501 comprises a plurality of metallization layer 5503₁ to 5503_{M}. In some embodiments, the metallization layer 5503_{M} is the final metallization layer of the interconnect structure 5501. In some embodiments, M may be between 1 and 5. In other embodiments, the metallization layer 5503_{M} is not the final metallization layer of the interconnect structure 5501 and additional metallization layers are formed over the metallization layer 5503_{M}.

In the illustrated embodiment, interconnects within different metallization layers of the interconnect structure 5501 have different structures. In particular, interconnects with different sizes may have different structures and may be formed using different process steps. In some embodiments, the metallization layer 5503₁ of the interconnect structure 5501 comprises conductive vias 5505₁ and conductive lines 5507₁. In some embodiments when a width of the conductive vias 5505₁ at the bottom of the conductive vias 5505, is between about 5 nm and about 10 nm, the conductive vias 5505₁ and conductive lines 5507₁ may be formed using process steps similar to process steps for forming the conductive vias 2101₁ and conductive lines 2103₁ described above with reference to FIGS. 2, 3A-3C, 4-6, 7A-7C, 8-10, 11A, 11B, 12A, 12B, 13-21, and the description is not repeated herein. In such embodiments, the metallization layer 5503₁ is similar to the metallization layer 3503₁ (see FIG. 35).

In some embodiments, the metallization layer 5503₂ of the interconnect structure 5501 comprises conductive vias 5505₂ and conductive lines 5507₂. In some embodiments when a width of the conductive vias 5505₂ at the bottom of the conductive vias 5505₂ is between about 8 nm and about 14 nm, the conductive vias 5505₂ and conductive lines 5507₂ may be formed using process steps similar to process steps for forming the conductive vias 4401₂ and conductive lines 4403₂ described above with reference to FIG. 47, and the description is not repeated herein. In such embodiments, the metallization layer 5503₂ is similar to the metallization layer 5003₂ (see FIG. 50). Furthermore, the metallization layer 5503₁ and the metallization layer 5503₂ have interconnects with different structures.

In some embodiments, the metallization layer 5503_{M} of the interconnect structure 5501 comprises conductive vias 5505_{M} and conductive lines 5507_{M}. In the illustrated embodiment, a width of the conductive vias 5505_{M} is greater than the width of the conductive vias 5505₁ and the width of the conductive vias 5505₂. In some embodiments when the width of the conductive vias 5505_{M} at the bottom of the conductive vias 5505_{M} is between about 15 nm and about 30 nm, the conductive vias 5505_{M} and conductive lines 5507_{M} may be formed using process steps similar to the process steps for forming the conductive vias 2101_{M} and conductive lines 2103_{M} described above with reference to FIG. 28, with the distinction that the surface modification process steps described above with reference to FIGS. 3A-3C, 4-6, 7A-7C, 8-10, 11A, 11B, 12A, 11B, 13, and 14 are omitted. In such embodiments, instead of forming the barrier layer 1501, the barrier layer 5509 is formed over and in physical contact with the conductive line of the underlying metallization layer. Accordingly, the metallization layer 5503_{M} and the metallization layer 5503₁ have interconnects with different structures. Furthermore, the metallization layer 5503_{M} and the metallization layer 5503₂ have interconnects with different structures. In some embodiments, the barrier layer 5509 may comprise titanium, titanium nitride, tantalum, tantalum nitride, a combination thereof, a multilayer thereof, or the like, and may be deposited using ALD, CVD, PVD, a combination thereof, or the like.

In some embodiments, interconnects of the metallization layers interposed between the metallization layer 5503₂ and the metallization layer 5503_{M}, may have different structures depending on the size of the interconnects. In some embodiments when widths of vias are between about 5 nm and about 10 nm, interconnects are formed to have structures similar to interconnects (such as the conductive vias 5505₁ and the conductive lines 5507₁) of the metallization layer 5503₁. In some embodiments when widths of vias are between about 8 nm and about 14 nm, interconnects are formed to have structures similar to interconnects (such as the conductive vias 5505₂ and the conductive lines 5507₂) of the metallization layer 5503₂. In some embodiments when widths of vias are between about 15 nm and about 30 nm, interconnects are formed to have structures similar to interconnects (the conductive vias 5505_{M} and the conductive lines 5507_{M}) of the metallization layer 5503_{M}.

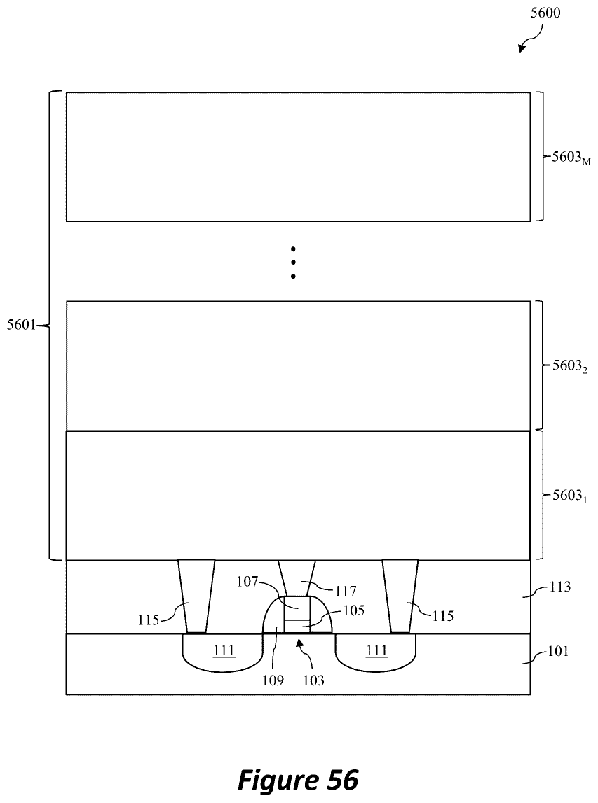

FIG. 56 illustrates a cross-sectional view of a semiconductor device 5600 in accordance with some embodiments. In some embodiments, some features of the semiconductor device 5600 are similar to features of the semiconductor device 100 (see FIG. 28), with similar features being labeled by similar numerical references. In some embodiments, the semiconductor device 5600 further includes an interconnect structure 5601 formed over the one or more ILD layers 113 and the contact plugs 115 and 117. In some embodiments, the interconnect structure 5601 comprises metallization layers 5603₁ to 5603_{M}. In some embodiments, M may be between 1 and 5. In some embodiments, each of the metallization layers 5603₁ to 5603_{M} may be similar to any of metallization layers 203₂, 3003₂, 3503₂, 3803₂, 4103₂, and 5003₂ (see FIGS. 28, 30, 35, 38, 47, and 50, respectively). In some embodiments, each or some of the metallization layers 5603₁ to 5603_{M} may have a similar structure.

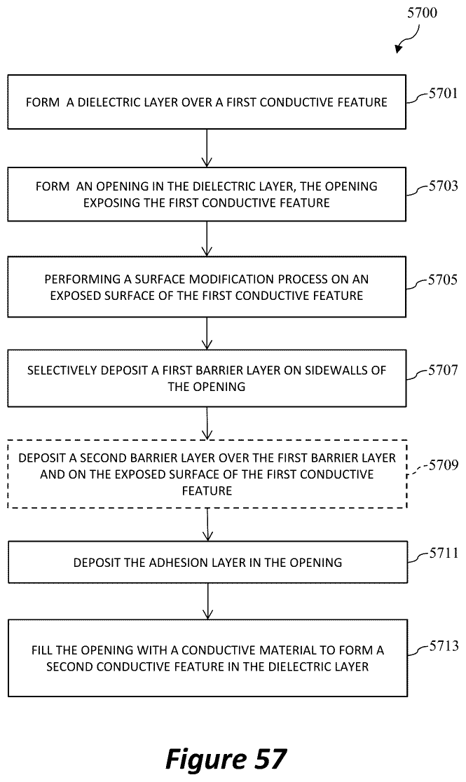

FIG. 57 is a flow diagram illustrating a method 5700 of forming an interconnect structure in accordance with some embodiments. The method 5700 starts with step S701, where a dielectric layer is formed over a first conductive feature as described above with reference to FIG. 2. In step S703, an opening is formed in the dielectric layer, such that the opening exposes the first conductive feature as described above with reference to FIG. 2. In step S705, a surface modification process is performed on an exposed surface of the first conductive feature as described above with reference to FIGS. 5 and 6. In step S707, a first barrier layer is selectively deposited on sidewalls of the opening as described above with reference to FIG. 15. In step S709, a second barrier layer is deposited over the first barrier layer and on the exposed surface of the first conductive feature as described above with reference to FIG. 42. In some embodiments, step S709 is omitted. In step S711, an adhesion layer is deposited in the opening as described above with reference to FIG. 19. In step S713, the opening is filled with a conductive material to form a second conductive feature in the dielectric layer as described above with reference to FIGS. 20 and 21.

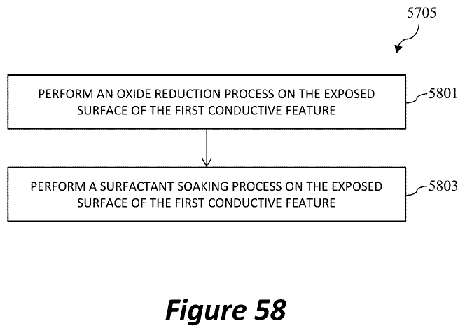

FIG. 58 is a flow diagram illustrating the surface modification process 5705 of the method 5700 (see FIG. 57) in accordance with some embodiments. The surface modification process 5705 starts with step S801, where an oxide reduction process is performed on the exposed surface of the first conductive feature as described above with reference to FIG. 5. In step S803, a surfactant soaking process is performed on the exposed surface of the first conductive feature as described above with reference to FIG. 6.

Embodiments may achieve advantages. Various embodiments discussed herein allow for reducing an amount (or volume) of a barrier layer within an interconnect (such as, for example, a conductive via) and, as a result, reducing a contact resistance between interconnects.

In accordance with an embodiment, a method includes depositing a dielectric layer over a conductive feature. The dielectric layer is patterned to form an opening therein. The opening exposes a first portion of the conductive feature. A first barrier layer is deposited on a sidewall of the opening. The first portion of the conductive feature remains exposed at the end of depositing the first barrier layer. In an embodiment, the method further includes depositing a second barrier layer over the first barrier layer in the opening, the second barrier layer being in physical contact with the first portion of the conductive feature. In an embodiment, the first barrier layer is separated from the first portion of the conductive feature by the second barrier layer. In an embodiment, the method further includes: before depositing the first barrier layer, removing a native oxide layer from the first portion of the conductive feature; and before depositing the first barrier layer, performing a surfactant soaking process on the first portion of the conductive feature, the surfactant soaking process suppressing a deposition rate of a first barrier material of the first barrier layer over the first portion of the conductive feature. In an embodiment, the surfactant soaking process forms a surfactant layer over the first portion of the conductive feature. In an embodiment, the surfactant layer comprises a monolayer of alkene molecules or a monolayer of alkyne molecules. In an embodiment, the method further includes: depositing an adhesion layer over the first barrier layer in the opening, the adhesion layer being in physical contact with the first portion of the conductive feature; and filling the opening with a conductive material.

In accordance with another embodiment, a method includes forming a dielectric layer over a first conductive feature. An opening is formed in the dielectric layer. The opening exposes a first portion of the first conductive feature. A second conductive feature is formed in the opening. Forming the second conductive feature includes performing a surface modification process on a top surface of the first portion of the first conductive feature. The surface modification process suppresses a deposition rate of a first barrier material over the top surface of the first portion of the first conductive feature. A first barrier layer including the first barrier material is selectively deposited on a sidewall of the opening. In an embodiment, performing the surface modification process includes: performing an oxide reduction process on the top surface of the first portion of the first conductive feature, the oxide reduction process removing a native oxide layer from the first portion of the first conductive feature; and performing a surfactant soaking process on the top surface of the first portion of the first conductive feature, the surfactant soaking process forming a surfactant layer over the top surface of the first portion of the first conductive feature. In an embodiment, the surfactant layer includes alkene molecules or alkyne molecules. In an embodiment, performing the oxide reduction process includes performing a plasma process on the top surface of the first portion of the first conductive feature. In an embodiment, the method further includes depositing an adhesion layer over the first barrier layer and on a bottom of the opening, the adhesion layer being in physical contact with the top surface of the first portion of the first conductive feature. In an embodiment, the method further includes depositing a second barrier layer including a second barrier material over the first barrier layer and on a bottom of the opening, the second barrier layer being in physical contact with the top surface of the first portion of the first conductive feature.

In accordance with yet another embodiment, a semiconductor structure includes a first conductive feature, a dielectric layer over the first conductive feature, and a second conductive feature within the dielectric layer and in electrical contact with the first conductive feature. A top surface of the first conductive feature has a first region and a second region different from the first region. The dielectric layer covers the first region of the top surface of the first conductive feature. The dielectric layer does not cover the second region of the top surface of the first conductive feature. The second conductive feature includes a conductive material and a first barrier layer interposed between a sidewall of the conductive material and a sidewall of the dielectric layer. The first barrier layer does not cover the second region of the top surface of the first conductive feature. In an embodiment, the semiconductor structure further includes an adhesion layer interposed between the sidewall of the conductive material and the first barrier layer, where the adhesion layer covers the second region of the top surface of the first conductive feature. In an embodiment, the adhesion layer is in physical contact with the sidewall of the dielectric layer. In an embodiment, the adhesion layer is separated from the sidewall of the dielectric layer by the first barrier layer. In an embodiment, the semiconductor structure further includes a second barrier layer interposed between the sidewall of the conductive material and the first barrier layer, where the second barrier layer covers the second region of the top surface of the first conductive feature. In an embodiment, an interface between the first barrier layer and the second barrier layer is in physical contact with the sidewall of the dielectric layer. In an embodiment, an interface between the first barrier layer and the second barrier layer is in physical contact with the second region of the top surface of the first conductive feature.

In accordance with yet another embodiment, a method includes forming a first conductive feature in a first dielectric layer. A second dielectric layer is formed over the first conductive feature and the first dielectric layer. An opening is formed in the second dielectric layer. The opening exposes a top surface of the first conductive feature. The top surface of the first conductive feature includes a first metallic material and a second metallic material different from the first metallic material. A native oxide layer is removed from the top surface of the first conductive feature. A surfactant soaking process is performed on the top surface of the first conductive feature. The surfactant soaking process forms a surfactant layer over the top surface of the first conductive feature. A first barrier layer is deposited on a sidewall of the opening. The surfactant layer remains exposed at the end of depositing the first barrier layer.

In an embodiment, the surfactant soaking process includes: soaking the top surface of the first conductive feature in a first gas including first surfactant molecules, the first surfactant molecules including unsaturated carbon functional groups; and soaking the top surface of the first conductive feature in a second gas including second surfactant molecules, the second surfactant molecules including nitrogen-based functional groups, where the surfactant layer includes the first surfactant molecules and the second surfactant molecules. In an embodiment, the first surfactant molecules are adsorbed on the first metallic material through the unsaturated carbon functional groups. In an embodiment, the second surfactant molecules are adsorbed on the second metallic material through the nitrogen-based functional groups. In an embodiment, the surfactant soaking process includes soaking the top surface of the first conductive feature in a gas including a mixture of first surfactant molecules and second surfactant molecules, the first surfactant molecules including unsaturated carbon functional groups, and the second surfactant molecules including nitrogen-based functional groups, where the surfactant layer includes the first surfactant molecules and the second surfactant molecules. In an embodiment, the surfactant soaking process includes soaking the top surface of the first conductive feature in a gas including surfactant molecules, the surfactant molecules including unsaturated carbon functional groups and nitrogen-based functional groups, wherein the surfactant layer includes the surfactant molecules. In an embodiment, the method further includes: depositing an adhesion layer over the first barrier layer in the opening, where the surfactant layer remains exposed at the end of depositing the adhesion layer; and removing the surfactant layer to expose the top surface of the first conductive feature.

In accordance with yet another embodiment, a method includes depositing a capping layer over a first conductive feature. The first conductive feature includes a first metallic material. The capping layer includes a second metallic material. The second metallic material is more electropositive than the first metallic material. A dielectric layer is deposited over the capping layer. A patterning process is performed on the dielectric layer to form an opening extending through the dielectric layer. The patterning process partially removes an exposed portion the capping layer such that a bottom of the opening exposes a first metallic surface including the first metallic material of the capping layer and the second metallic material of the first conductive feature. A surfactant soaking process is performed on the first metallic surface. The surfactant soaking process suppresses a first deposition rate of a barrier material and a second deposition rate of an adhesion material over the first metallic surface. A barrier layer including the barrier material is selectively deposited on a sidewall of the opening. An adhesion layer including the adhesion material is selectively deposited over the barrier layer in the opening. In an embodiment, the method further includes, before performing the surfactant soaking process, performing a plasma process to remove a native oxide layer from the first metallic surface. In an embodiment, the surfactant soaking process includes: soaking the first metallic surface in a first gas including first surfactant molecules, the first surfactant molecules including unsaturated carbon functional groups, where the first surfactant molecules are adsorbed on the first metallic material of the first metallic surface through the unsaturated carbon functional groups; and soaking the first metallic surface in a second gas including second surfactant molecules, the second surfactant molecules including nitrogen-based functional groups, where the second surfactant molecules are adsorbed on the second metallic material of the first metallic surface through the nitrogen-based functional groups. In an embodiment, soaking the first metallic surface in the first gas including the first surfactant molecules is performed in a first process chamber, and soaking the first metallic surface in the second gas including the second surfactant molecules is performed in a second process chamber different from the first process chamber. In an embodiment, soaking the first metallic surface in the first gas including the first surfactant molecules and soaking the first metallic surface in the second gas including the second surfactant molecules are performed in a same process chamber. In an embodiment, the surfactant soaking process includes soaking the first metallic surface in a gas including a mixture of first surfactant molecules and second surfactant molecules, the first surfactant molecules including unsaturated carbon functional groups, and the second surfactant molecules including nitrogen-based functional groups, where the first surfactant molecules are adsorbed on the first metallic material of the first metallic surface through the unsaturated carbon functional groups, and where the second surfactant molecules are adsorbed on the second metallic material of the first metallic surface through the nitrogen-based functional groups. In an embodiment, the surfactant soaking process includes soaking the first metallic surface in a gas including surfactant molecules, the surfactant molecules including unsaturated carbon functional groups and nitrogen-based functional groups, where a first group of the surfactant molecules is adsorbed on the first metallic material of the first metallic surface through the unsaturated carbon functional groups, and where a second group of the surfactant molecules is adsorbed on the second metallic material of the first metallic surface through the nitrogen-based functional groups.

In accordance with yet another embodiment, a semiconductor structure includes a first conductive feature, a dielectric layer over the first conductive feature, and a second conductive feature within the dielectric layer and in electrical contact with the first conductive feature. The second conductive feature includes a conductive layer, a barrier layer interposed between a sidewall of the conductive layer and a sidewall of the dielectric layer, and an adhesion layer interposed between the sidewall of the conductive layer and the barrier layer. The barrier layer does not extend between a bottom surface of the conductive layer and a top surface of the first conductive feature. The adhesion layer does not extend between the bottom surface of the conductive layer and the top surface of the first conductive feature. In an embodiment, the conductive layer is in physical contact with the sidewall of the dielectric layer. In an embodiment, the semiconductor structure further includes a capping layer between the first conductive feature and the dielectric layer. In an embodiment, the conductive layer is in physical contact with a sidewall of the capping layer. In an embodiment, the barrier layer is in physical contact with a sidewall of the capping layer. In an embodiment, a portion of the conductive layer is interposed between a bottom surface of the adhesion layer and the top surface of the first conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first conductive feature in a first dielectric layer;
forming a second dielectric layer over the first conductive feature and the first dielectric layer;
forming an opening in the second dielectric layer, the opening exposing a top surface of the first conductive feature;
performing a surfactant soaking process on the top surface of the first conductive feature, the surfactant soaking process forming a surfactant layer over the top surface of the first conductive feature;
depositing a first barrier layer on a sidewall of the opening, wherein the surfactant layer remains exposed after depositing the first barrier layer;
depositing a first adhesion layer over the first barrier layer;
after forming the first adhesion layer, removing the surfactant layer; and
forming a second conductive feature in the opening over the first adhesion layer.

2. The method of claim 1, wherein the second conductive feature contacts the second dielectric layer.

3. The method of claim 1, further comprising:
prior to forming the second dielectric layer, forming a capping layer over the top surface of the first conductive feature.

4. The method of claim 3, wherein the second conductive feature contacts the capping layer.

5. The method of claim 1, wherein the second conductive feature comprises a seed layer and a conductive fill over the seed layer.

6. The method of claim 1, wherein the first barrier layer contacts the second conductive feature.

7. The method of claim 1, wherein the first adhesion layer contacts the first conductive feature.

8. A method comprising:
forming a first conductive feature in a first dielectric layer;
forming a second dielectric layer over the first conductive feature and the first dielectric layer;
forming an opening in the second dielectric layer, the opening exposing a top surface of the first conductive feature;
performing a surfactant soaking process on the top surface of the first conductive feature, the surfactant soaking process forming a surfactant layer over the top surface of the first conductive feature;
depositing a first barrier layer on a sidewall of the opening, wherein the surfactant layer remains exposed after depositing the first barrier layer;
after forming the first barrier layer, removing the surfactant layer; and
after removing the surfactant layer, depositing a first adhesion layer over the first barrier layer; and
forming a second conductive feature in the opening over the first adhesion layer.

9. The method of claim 8, further comprising:
after removing the surfactant layer and prior to depositing the first adhesion layer, forming a second barrier layer, wherein the first adhesion layer is formed over the second barrier layer.

10. The method of claim 9, wherein the first barrier layer and the second barrier layer comprise a same material.

11. The method of claim 9, wherein the second barrier layer contacts the second dielectric layer.

12. The method of claim 9, further comprising:
prior to forming the second dielectric layer, forming a capping layer over the top surface of the first conductive feature.

13. The method of claim 12, wherein the second barrier layer contacts the capping layer.

14. The method of claim 8, wherein a corner of the second conductive feature has a concave surface.

15. A method comprising:
forming a first conductive feature in a first dielectric layer;
forming a second dielectric layer over the first conductive feature and the first dielectric layer;
forming an opening in the second dielectric layer, the opening exposing a top surface of the first conductive feature;
performing a surfactant soaking process on the top surface of the first conductive feature, the surfactant soaking process forming a surfactant layer over the top surface of the first conductive feature;
depositing a first barrier layer on a sidewall of the opening, wherein the surfactant layer remains exposed after depositing the first barrier layer;
after forming the first barrier layer, forming a second barrier layer over the first barrier layer and along a bottom of the opening;
after forming the second barrier layer, depositing a first adhesion layer over the second barrier layer; and
forming a second conductive feature in the opening over the first adhesion layer.

16. The method of claim 15, further comprising:
prior to depositing the second barrier layer, removing the surfactant layer.

17. The method of claim 15, further comprising:
prior to forming the second dielectric layer, forming a capping layer over the top surface of the first conductive feature.

18. The method of claim 17, wherein the second barrier layer contacts the capping layer.

19. The method of claim 15, wherein a corner of the second conductive feature has a concave surface.

20. The method of claim 15, wherein the second barrier layer is spaced apart from the second dielectric layer.
